(19) United States
(12) Patent Application Publication
(10) Pub. No.: US 2025/0105039 A1
(43) Pub. Date: Mar. 27, 2025

(54) SUBSTRATE TRANSPORTING DEVICE AND SUBSTRATE PROCESSING DEVICE EQUIPPED WITH THE SAME

(71) Applicant: SCREEN Holdings Co., Ltd., Kyoto (JP)

(72) Inventors: Takuya SATO, Kyoto (JP); Hiroyuki KAWAHARA, Kyoto (JP)

(21) Appl. No.: 18/892,104

(22) Filed: Sep. 20, 2024

(30) Foreign Application Priority Data
Sep. 21, 2023 (JP) 2023-155673

(51) Int. Cl. H01L 21/67; B65G 1/04; H01L 21/687

(52) U.S. Cl. CPC H01L 21/67259; B65G 1/04; H01L 21/68707; B65G 2201/0297; B65G 2203/041; B65G 2203/044

(57) ABSTRACT

A substrate transporting device includes the following elements. A substrate transporting device includes a transporting unit having a holding hand that holds the substrate, and being configured to transport the substrate by advancing/retreating the holding hand from the carry-in/out port of the accommodating container to a gap between the substrates; a thickness shape information collecting unit configured to collect thickness shape information based on an outer edge of the substrate for each substrate while the substrate is accommodated in the accommodating container; a calculation unit configured to calculate height information of a gap between two vertically adjacent substrates to which the holding hand advances/retreats based on the thickness shape information of the two substrates when the transporting unit carries-in/out the substrates to/from the accommodating container; and a control unit configured to control transport of the transporting unit based on the height information.

### BACKGROUND OF THE INVENTION

### (1) Field of the Invention

The present invention relates to a substrate transporting device that transports a substrate such as a semiconductor substrate, a substrate for a flat panel display (FPD) such as a liquid crystal display or an organic electroluminescence (EL) display device, a glass substrate for a photomask, or a substrate for an optical disk, and a substrate processing device including the substrate transporting device.

### (2) Description of the Related Art

Conventionally, this type of device includes a storage unit, a robot arm, a photographing unit, and a control unit. For example, Japanese Patent Publication No. 2023-30876 is referred to.

The storage unit stores a plurality of substrates stacked in a state of being spaced apart in the vertical direction. In the storage unit, the substrate is carried in/out through a carry-in/out port opened on one surface. The robot arm transports the substrate. The robot arm includes a substrate holding hand that holds a substrate. The robot arm advances/retreats the substrate holding hand to/from the carry-in/out port of the storage unit, and carries in/out the substrate to/from the storage unit. The photographing unit is attached to the substrate holding hand. The photographing unit photographs a plurality of substrates stored in the storage unit. The control unit acquires a transport gap that is a gap in which the substrate holding hand advances/retreats based on an image photographed by the photographing unit. The control unit causes the substrate holding hand to advance/retreat to/from the storage unit to transport the substrate based on the acquired size of the transport gap.

However, the conventional example having such a configuration has the following problems.

Therefore, the substrate may be warped into a complicated shape. This is because films having different thermal expansion coefficients are applied in a semiconductor process, and various heat treatments are further performed. For example, the substrate may be three-dimensionally warped. Representative warps include bowl, umbrella, and half-pipe. The substrate warped in a bowl shape has a central portion recessed and an outer peripheral edge located at a high position. The substrate warped in an umbrella shape has a shape in which the upper and lower sides of the substrate warped in a bowl shape are inverted. That is, the substrate warped in an umbrella shape has an outer peripheral edge located at a low position and a central portion raised. The substrate warped in a half-pipe shape has a circular arc shape when viewed from the central axis direction with the substrate surfaces spaced apart around the central axis such that the cylinder extends along the central axis.

That is, when these warped substrates are stored in the storage unit, the height on the near side of the end face of the substrate located on the carry-in/out port side of the storage unit is different from the height at which a part of the substrate is located on the far side in the direction in which the substrate holding hand advances/retreats. The transport gap in the prior art reflects the height of the end face of the substrate located on the carry-in/out port side of the storage unit. That is, the height on the near side of the end face of the substrate is reflected.

However, the height in the depth direction in which the substrate holding hand advances/retreats is not reflected. Therefore, in the transport of the three-dimensionally warped substrate, even if the advancing/retreating height of the substrate holding hand is adjusted according to the transport gap, there is a problem that the substrate and the substrate holding hand may interfere with each other.

### SUMMARY OF THE INVENTION

The present invention has been made in view of such circumstances, and an object of the present invention is to provide a substrate transporting device capable of preventing interference at the time of carry-in/out even with a three-dimensionally warped substrate, and a substrate processing device equipped with the substrate transporting device.

In order to achieve such an object, the present invention has the following configuration.

That is, there is provided a substrate transporting device for transporting a substrate with an accommodating container capable of stacking and accommodating a plurality of substrates with a gap and having a carry-in/out port on one side surface, the substrate transporting device including a transporting unit having a holding hand that holds the substrate, and being configured to transport the substrate by advancing/retreating the holding hand from the carry-in/out port of the accommodating container to a gap between the substrates; a thickness shape information collecting unit configured to collect thickness shape information based on an outer edge of the substrate for each substrate when the substrate is viewed along an advancing/retreating direction of the holding hand in a state where the substrate is accommodated in the accommodating container; a calculation unit configured to calculate height information of a gap between two vertically adjacent substrates to which the holding hand attempts to advance/retreat based on the thickness shape information of the two vertically adjacent substrates when the transporting unit carries-in/out the substrate to/from the accommodating container; and a control unit configured to control transport of the transporting unit based on the height information.

According to the present invention, when the substrate is viewed along the advancing/retreating direction of the holding hand in a state where the substrate is accommodated in the accommodating container, the thickness shape information collecting unit collects thickness shape information based on the outer edge of the substrate for each substrate. The thickness shape information includes the thickness of the substrate not only on the near side of the carry-in/out port but also on the far side in the advancing/retreating direction of the holding hand. The thickness shape information includes the thickest dimension between the near side and the far side in the advancing/retreating direction of the holding hand. The calculation unit calculates height information of a gap between two vertically adjacent substrates to which the holding hand attempts to advance and retreat based on the thickness shape information. The control unit controls the transport of the transporting unit in consideration of the thickness of the three-dimensionally warped substrate based on the calculated height information. Therefore, even if the substrate is three-dimensionally warped, interference of the holding hand can be prevented at the time of carry-in/out.

Furthermore, in the present invention, the thickness shape information preferably includes an end face height position which is a position in a height direction of an end face on the carry-in/out port side in the substrates housed in the accommodating container, and a far side height position which is on a far side of the end face and at which a part of the substrate is located away from the end face height position in the height direction.

The thickness shape information includes not only the end surface height position of the substrate but also the far side height position located on the far side of the end face. Therefore, the thickness shape information includes the thickest dimension between the near side and the far side in the advancing/retreating direction of the holding hand.

In addition, in the present invention, a relative moving unit configured to move a relative position between the accommodating container and the thickness shape information collecting unit in a height direction, and a storage unit configured to store the thickness shape information of each substrate obtained by relatively moving the accommodating container and the thickness shape information collecting unit by the relative moving unit are further preferably provided, wherein the thickness shape information collecting unit collects the thickness shape information at a plurality of places in a horizontal direction orthogonal to an advancing/retreating direction of the holding hand, and the calculation unit calculates the height information of a gap between vertically adjacent substrates based on the thickness shape information of each substrate stored in the storage unit.

The thickness shape information collecting unit collects the thickness shape information at a plurality of places in the horizontal direction orthogonal to the advancing/retreating direction of the holding hand. The calculation unit can calculate height information of a gap between vertically adjacent substrates based on the thickness shape information of each substrate stored in the storage unit. Therefore, interference with the holding hand extending in the horizontal direction orthogonal to the advancing/retreating direction to hold the substrate can be prevented. In addition, even a substrate having the thickest thickness in the height direction at a position other than the central portion horizontally orthogonal to the advancing/retreating direction when viewed from the advancing/retreating direction of the holding hand can be handled.

Furthermore, in the present invention, the thickness shape information collecting unit preferably includes a light projecting portion that emits light toward an outer side surface of the substrate from a first direction toward the substrate; and a light receiving portion that receives light emitted from the light projecting portion and reflected from a direction opposite to the first direction.

The thickness shape information collecting unit can collect the thickness shape information of the substrate viewed from the advancing/retreating direction of the holding hand in a non-contact manner with the substrate based on the height at which the light receiving portion can receive the reflected light.

Furthermore, in the present invention, the thickness shape information collecting unit further preferably includes a reflecting portion that is disposed inside the accommodating container facing the light projecting portion with the substrate interposed therebetween and reflects light from the light projecting portion at the plurality of places.

Since the reflecting portion is provided inside the accommodating container, the light receiving portion can reliably receive the reflected light. Therefore, the thickness shape information collecting unit can reliably collect the thickness shape information of the substrate. Furthermore, in the present invention, the light receiving portion preferably receives the reflected light from the substrate.

Since the reflected light from the substrate is directly received by the light receiving portion, there is no need to provide the reflecting portion. Therefore, a commercially available accommodating container can be used as it is, and the configuration of the present invention can be simplified.

Furthermore, in the present invention, an opening/closing mechanism that attaches/detaches a lid attached to the carry-in/out port of the accommodating container, and lowers the lid downward along the carry-in/out port when detaching the lid is further preferably provided, wherein the light projecting portion and the light receiving portion are preferably attached to the opening/closing mechanism.

Since the light projecting portion and the light receiving portion are attached to the opening/closing mechanism, the relative moving unit does not need to be separately provided. Therefore, the configuration of the present invention can be simplified.

In addition, in the present invention, preferably, the accommodating container is made of a material optically transparent to the irradiation light from the light projecting portion, a reflecting portion that reflects the irradiation light from the light projecting portion is further provided, and the reflecting portion is disposed outside the accommodating container.

In the present invention, the light projecting portion, the light receiving portion, and the reflecting portion can be provided outside the accommodating container. Therefore, if the accommodating container is made of an optically transparent material, there is no need to modify the accommodating container such as attaching a reflecting portion.

Furthermore, in the present invention, preferably, the thickness shape information collecting unit includes a light projecting portion that irradiates an outer side surface of the substrate with light from a first direction toward the substrate, and a light receiving portion that has a function of receiving irradiation light from the light projecting portion, and is disposed outside the accommodating container in a direction opposite to a first direction with the substrate therebetween; and the accommodating container is made of a material optically transparent to the irradiation light from the light projecting portion.

Since the thickness shape information collecting unit uses a transmissive detection method for the thickness shape information, the thickness shape information collecting unit is less likely to be adversely affected by the reflectance of the detection target and the reflectance of the surrounding configuration. Therefore, the present invention can improve the detection accuracy of the thickness shape information. Furthermore, in the present invention, the light projecting portion and the light receiving portion can be provided outside the accommodating container. Therefore, if the accommodating container is made of an optically transparent material, there is no need to modify the accommodating container such as attaching a reflecting portion.

Furthermore, in the present invention, the thickness shape information collecting unit preferably includes a photographing unit that is arranged on the carry-in/out port side of the accommodating container and photographs a projection image as the thickness shape information.

The thickness shape information collecting unit can collect the thickness shape information by photographing the projection image by the photographing unit. Therefore, the thickness shape information collecting unit may include the photographing unit only on the carry-in/out port side of the accommodating container. As a result, the present invention can simplify the configuration of the thickness shape information collecting unit. When the field of view of the photographing unit is expanded in the direction in which the plurality of substrates are stacked, the thickness shape information collecting unit can collect the plurality of pieces of thickness shape information at the same time.

Furthermore, in the present invention, preferably, the photographing unit is configured to be able to adjust a focusing position, the control unit instructs the focusing position to the photographing unit, and the photographing unit adjusts the focusing position to at least two places of a first focusing position obtained by focusing on a part of the substrate on the carry-in/out port side and a second focusing position obtained by focusing on a part of the substrate on a far side than the first focusing position based on the instruction of the focusing position.

In consideration of the diameter of the substrate, for example, in the projection image focused on the end face of the substrate, the center side of the substrate in the advancing/retreating direction of the holding hand is blurred. Conversely, for example, in the projection image focused on the center side of the substrate in the advancing/retreating direction of the holding hand, the end face of the substrate is blurred. Therefore, in the present invention, the focusing position is adjusted to the first focusing position and the second focusing position. That is, the thickness shape information collecting unit collects the thickness shape information from the projection image focused on at least two places of the projection image at the first focusing position and the projection image at the second focusing position. As a result, the thickness shape information collecting unit can accurately collect the thickness shape information based on the projection image.

Furthermore, in the present invention, preferably, an image storage unit configured to store the projection image photographed by the photographing unit is further provided, wherein the control unit causes the photographing unit to perform photographing in a state where a plurality of substrates having a first thickness and without warpage are accommodated in the accommodating container, and causes the image storage unit to store the projection image collected at this time as a first reference image, the control unit causes the photographing unit to perform photographing in a state where a plurality of substrates having a second thickness different from the first thickness and without warpage are accommodated in the accommodating container, and causes the image storage unit to store the projection image collected at this time as a second reference image, and the thickness shape information collecting unit collects the thickness shape information by calculating a dimension in the projection image based on a known dimension in the first reference image and the second reference image stored in the image storage unit when performing substrate processing as a product.

The control unit causes the storage to store the first reference image and the second reference image in advance. When performing substrate processing as a product, the thickness shape information collecting unit calculates dimensions in the projection image based on known dimensions in the first reference image and the second reference image to collect the thickness shape information. Since the thickness shape information collecting unit performs calibration using the first reference image and the second reference image, the thickness shape information collecting unit can accurately collect the thickness shape information based on the dimension of the projection image when performing the substrate processing as a product.

Furthermore, in the present invention, preferably, the thickness shape information collecting unit includes a light projecting portion that irradiates an outer side surface of the substrate with light from a first direction toward the substrate, and a line sensor that has a function of receiving irradiation light from the light projecting portion, that is disposed outside the accommodating container in a direction opposite to a first direction with the substrate therebetween, and that has a detection area that is long in a stacking direction of the plurality of substrates accommodated inside the accommodating container; and the accommodating container is made of a material optically transparent to the irradiation light from the light projecting portion.

The thickness shape information collecting unit includes a light projecting portion and a line sensor. Since the line sensor is used, it is possible not to move in the direction in which the plurality of substrates are stacked and to reduce the number of movements. Therefore, the thickness shape information of the plurality of substrates W can be efficiently collected.

Furthermore, in the present invention, the calculation unit preferably calculates the height information based on a shape of an outer edge of a target substrate that is a target of transport by the transporting unit and a substrate adjacent to the target substrate in the thickness shape information.

The height information is calculated based on the thickness shape information of the target substrate transported from the accommodating container and the substrate adjacent to the target substrate. Therefore, even if the holding hand rises/lowers when the target substrate is carried out of the accommodating container, the control unit can control the transport so as not to interfere with the adjacent substrate.

In order to achieve such an object, the present invention has the following configuration.

That is, there is provided a substrate processing device including a substrate transporting device for transporting a substrate with an accommodating container capable of stacking and accommodating a plurality of substrates with a gap and having a carry-in/out port on one side surface and a processing unit configured to perform a predetermined process on a substrate transported by the substrate transporting device, wherein
the substrate transporting device includes a transporting unit having a holding hand that holds the substrate, and being configured to transport the substrate by advancing/retreating the holding hand from the carry-in/out port of the accommodating container to a gap between the substrates; a thickness shape information collecting unit configured to collect thickness shape information based on an outer edge of the substrate for each substrate when the substrate is viewed along an advancing/retreating direction of the holding hand in a state where the substrate is accommodated in the accommodating container; a calculation unit configured to calculate height information of a gap between two vertically adjacent substrates to which the holding hand attempts to advance/retreat based on the thickness shape information of the two vertically adjacent substrates when the transporting unit carries-in/out the substrates to/from the accommodating container; and a control unit configured to control transport of the transporting unit based on the height information.

The substrate processing device includes a processing unit configured to perform a predetermined process on the substrate transported by the substrate transporting device. Therefore, even if the substrate warped three-dimensionally is accommodated in the accommodating container, the substrate can be transported without interfering with the holding hand. Therefore, the substrate warped three-dimensionally can be appropriately processed by the processing unit.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a plan view illustrating an overall configuration of a substrate processing device according to a first example;

FIG. 2 is a diagram of the substrate processing device of FIG. 1 as viewed from the back side X;

FIGS. 3A to 3E are side views illustrating the configuration and operation of a carry-in/out block;

FIGS. 4A and 4B are examples of the bowl shaped warped substrate, where FIG. 4A is a view as viewed from the front-back direction X, and FIG. 4B is a view as viewed from the width direction Y;

FIGS. 5A and 5B are examples of the umbrella shaped warped substrate, where FIG. 5A is a view as viewed from the front-back direction X, and FIG. 5B is a view as viewed from the width direction Y;

FIGS. 6A and 6B are examples of the half-pipe shaped warped substrate, where FIG. 6A is a view as viewed from the front-back direction X, and FIG. 6B is a view as viewed from the width direction Y;

FIG. 7 is a block diagram illustrating an example of a control system;

FIG. 8 is a front view illustrating a configuration of a thickness shape information collecting unit according to a first example;

FIG. 9 is a plan view illustrating a configuration of a thickness shape information collecting unit according to the first example;

FIG. 10 is a schematic view for explaining thickness shape information;

FIG. 11 is a front view illustrating a configuration of a thickness shape information collecting unit according to a second example;

FIG. 12 is a plan view illustrating a configuration of a thickness shape information collecting unit according to the second example;

FIG. 13 is a plan view illustrating a configuration of a thickness shape information collecting unit according to a third example;

FIG. 14 is a plan view illustrating a configuration of a thickness shape information collecting unit according to a fourth example;

FIG. 15 is a plan view illustrating a configuration of a thickness shape information collecting unit according to a fifth example;

FIG. 16 is a block diagram illustrating an example of a thickness shape information collecting unit according to the fifth example;

FIGS. 17A to 17C are schematic views for explaining a focusing position and a synthesized image;

FIGS. 18A to 18C are schematic views describing examples of calibration in image processing;

FIG. 19 is a side view illustrating an example of a thickness shape information collecting unit according to a sixth example; and

FIG. 20 is a plan view illustrating an example of the thickness shape information collecting unit according to the sixth example.

### DESCRIPTION OF THE PREFERRED EMBODIMENTS Hereinafter, preferred examples of the present invention will be described in detail with reference to the drawings.

### DESCRIPTION OF EMBODIMENTS

Hereinafter, the present invention will be described with reference to various examples.

### First Example

Hereinafter, a first example of the present invention will be described with reference to the drawings.

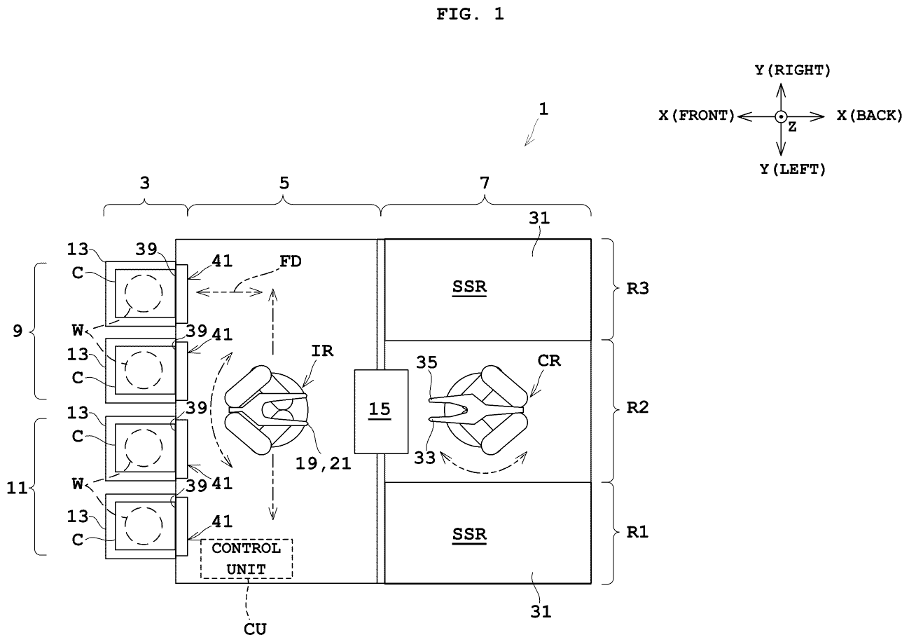

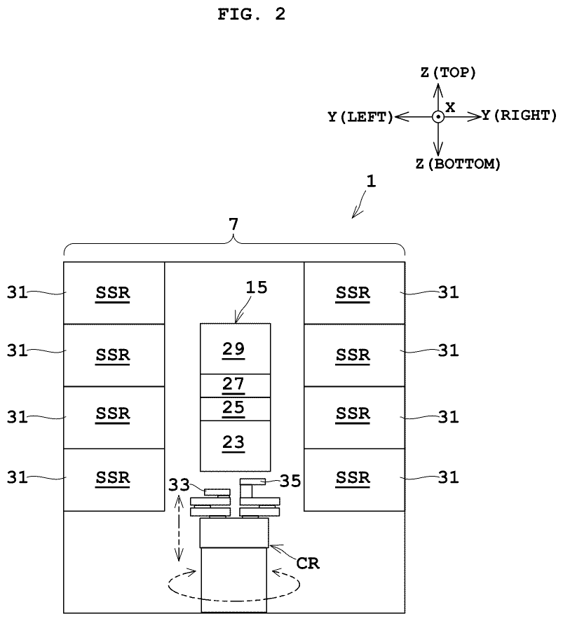

FIG. 1 is a plan view illustrating an overall configuration of a substrate processing device according to a first example. FIG. 2 is a diagram of the substrate processing device of FIG. 1 as viewed from the back side X.

### 1. Overall Configuration

The substrate processing device 1 includes a carry-in/out block 3, an indexer block 5, and a processing block 7.

The substrate processing device 1 processes a substrate W. The substrate W has, for example, a circular shape in plan view. The substrate processing device 1 performs, for example, washing process on the substrate W. The substrate processing device 1 processes the substrate W in a single wafer processing in the processing block 7. In the single wafer processing, one substrate W is processed one by one in a state of a horizontal posture.

In the present specification, for the sake of convenience, a direction in which the carry-in/out block 3, the indexer block 5, and the processing block 7 are arranged is referred to as a “front-back direction X”. The front-back direction X is horizontal. Of the front-back direction X, the direction from the processing block 7 toward the carry-in/out block 3 is referred to as “front side”. A direction opposite to the front side is referred to as “back side”. A horizontal direction orthogonal to the front-back direction X is referred to as a “width direction Y”. One direction in the “width direction Y” is appropriately referred to as a “right side”. A direction opposite to the right side is referred to as “left side”. A direction perpendicular to the horizontal direction is referred to as a “vertical direction Z”. In each drawing, front, back, right, left, top, and bottom are appropriately shown for reference.

### 2. Carry-In/Out Block

The carry-in/out block 3 includes an input unit 9 and a dispensing unit 11. The input unit 9 and the dispensing unit 11 are arranged in the width direction Y. A plurality of (e.g., 25) substrates W are stacked and stored in one carrier C at constant intervals in a horizontal posture. The carrier C storing the unprocessed substrate W is placed on the input unit 9. The input unit 9 includes, for example, two placement tables 13 on which the carrier C is placed. The carrier C separates the surfaces of the substrates W from each other and accommodates the substrates W one by one. The carrier C accommodates the substrates, for example, in a posture in which the front surface of the substrate W is facing upward. As the carrier C, for example, there is a front opening unify pod (FOUP). The FOUP is a sealed container. The carrier C may be an open type container and may be of any type.

The dispensing unit 11 is disposed on the opposite side of the input unit 9 with the central portion in the width direction Y of the substrate processing device 1 in between. The dispensing unit 11 is disposed on the left side Y of the input unit 9. The dispensing unit 11 stores the processed substrate W in the carrier C and dispenses the processed substrate W by the carrier C. Similarly to the input unit 9, the dispensing unit 11 functioning in this manner includes, for example, two placement tables 13 for placing the carrier C. The input unit 9 and the dispensing unit 11 are also called load ports.

### 3. Indexer Block

The indexer block 5 is disposed adjacent to the back side X of the carry-in/out block 3 in the substrate processing device 1. The indexer block 5 includes an indexer robot IR and a delivery unit 15.

The indexer robot IR is configured to be rotatable about the vertical direction Z. The indexer robot IR is configured to be movable in the width direction Y. The indexer robot IR includes a first hand 19 and a second hand 21. FIG. 1 illustrates only one hand for the sake of illustration. Each of the first hand 19 and the second hand 21 holds one substrate W. The first hand 19 and the second hand 21 are configured to be able to independently advance/retreat in the front-back direction X. The indexer robot IR moves in the width direction Y and rotates about the vertical direction Z. The indexer robot IR advances and retreats the first hand 19 and the second hand 21 to deliver the substrate W to/from each cassette C. Similarly, the indexer robot IR delivers the substrate W to/from the delivery unit 15. A direction in which the first hand 19 and the second hand 21 move when delivering the substrate W to/from the carrier C is defined as an advancing/retreating direction FD.

The delivery unit 15 is disposed at a boundary with the processing block 7 in the indexer block 5. The delivery unit 15 is disposed, for example, at a central portion in the width direction Y. As illustrated in FIG. 2, the delivery unit 15 is formed to be long in the vertical direction Z.

The delivery unit 15 includes first inversion unit 23, a pass unit 25, a pass unit 27, and a second inversion unit 29 from the lower side to the upper side in vertical direction Z.

The first inversion unit 23 up-down inverts the substrate W received from the indexer block 5. The first inversion unit 23 inverts the horizontal posture of the substrate W. Specifically, the first inversion unit 23 converts the substrate W in which the front surface is facing upward to a posture in which the front surface is facing downward. In other words, the posture of the substrate W is converted to be a posture in which the back surface is facing upward.

The second inversion unit 29 performs the reverse operation. That is, the second inversion unit 29 up-down inverts the substrate W received from the processing block 7. The second inversion unit 29 converts the substrate W in which the front surface is facing downward to a posture in which the front surface is facing upward. In other words, the posture of the substrate W is converted to be a posture in which the back surface is facing downward.

The inverting directions of the first inversion unit 23 and the second inversion unit 29 may be opposite to each other. That is, the first inversion unit 23 converts the posture of the substrate W to be a posture in which the front surface is facing upward. That is, the second inversion unit 29 converts the posture of the substrate W to be a posture in which the back surface is facing upward.

The pass units 25 and 27 are used to deliver the substrate W between the indexer block 5 and the processing block 7. The pass unit 25 is used, for example, to transport the substrate W from the processing block 7 to the indexer block 5. The pass unit 27 is used, for example, to transport the substrate W from the indexer block 5 to the processing block 7. Note that the transporting directions of the substrates W in the pass units 25 and 27 may be opposite directions to each other.

### 4. Processing Block

The processing block 7 performs, for example, washing process on the substrate W. The washing process is, for example, a process that uses a brush in addition to the processing liquid. As illustrated in FIG. 1, for example, the processing block 7 is divided into a first row R1, a second row R2, and a third row R3 in the width direction Y. Specifically, the first row R1 is arranged on the left side Y. The second row R2 is arranged at the central portion in the width direction Y. In other words, the second row R2 is arranged on the right side Y of the first row R1. The third row R3 is arranged on the right side Y of the second row R2.

### 4-1. First Row

The first row R1 of the processing block 7 includes a plurality of processing units 31. The first row R1 includes, for example, four processing units 31. The first row R1 is arranged by stacking four processing units 31 in the vertical direction Z. Each processing unit 31 is, for example, a washing unit. The washing unit performs washing process on the substrate W. Examples of the washing unit include a front surface washing unit for performing washing process on the front surface of the substrate W and a back surface washing unit for performing washing process on the back surface of the substrate W. In the present example, a back surface washing unit SSR will be described as an example of the processing unit 31.

### 4-2. Second Row

The second row R2 of the processing block 7 includes a center robot CR. The center robot CR is configured to be rotatable about the vertical direction Z. The center robot CR is configured to be movable up and down in the vertical direction Z. The center robot CR includes, for example, a first hand 33 and a second hand 35. Each of the first hand 33 and the second hand 35 holds one substrate W. The first hand 33 and the second hand 35 are configured to be able to independently advance/retreat in the front-back direction X and the width direction Y.

### 4-3. Third Row

The third row R3 of the processing block 7 has a similar configuration as the first row R1. That is, the third row R3 includes the plurality of processing units 31. The third row R3 includes, for example, four processing units 31. The third row R3 is arranged by stacking four processing units 31 in the vertical direction Z. The processing units 31 in the first row R1 and the processing units 31 in the third row R3 are arranged facing each other in the width direction Y. As a result, the center robot CR can access the processing units 31 facing each other in the first row R1 and the third row R3 at the same height in the vertical direction Z.

The processing block 7 is configured as described above. Here, an operation example of the center robot CR will be briefly described. The center robot CR receives, for example, the substrate W from the first inversion unit 23. The center robot CR transports the substrate W to the back surface washing unit SSR in either the first row R1 and the third row R3. The back surface washing unit SSR performs washing process on the back surface of the substrate W. The center robot CR receives the substrate W subjected to the washing process in the back surface washing unit SSR in one of the first row R1 and the third row R3. The center robot CR transports the substrate W to the second inversion unit 29.

### 5. Placement Table

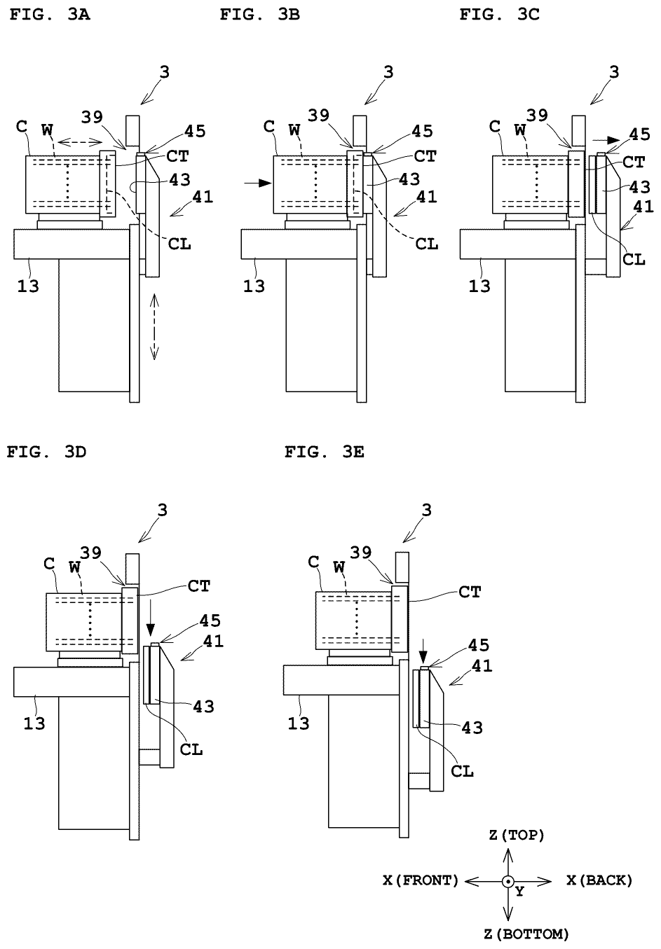

Here, the above-described carry-in/out block 3 will be described in detail with reference to FIGS. 1 and 3. FIGS. 3A to 3E are side views illustrating the configuration and operation of the carry-in/out block.

The carry-in/out block 3 includes a placement table 13, an opening 39, and a lid opening/closing mechanism 41. The carrier C is placed on the placement table 13. The placement table 13 includes a mechanism (not illustrated) that moves the carrier C in the front-back direction X. The placement table 13 can advance/retreat the carrier C with respect to the opening 39. The carrier C has a carry-in/out port CT. The carry-in/out port CT is formed on one side surface of the carrier C. The plurality of substrates W stacked and accommodated in the carrier C are carried in/out via the carry-in/out port CT. The carrier C includes a lid CL. The lid CL is configured to be freely attached and detached to/from the carry-in/out port CT of the carrier C. The lid CL seals the inside of the carrier C. When the lid CL is mounted to the carrier C, the atmosphere with the outside of the carrier C is shielded.

The lid opening/closing mechanism 41 includes an attachment/detachment unit 43 on the front side X. The attachment/detachment unit 43 detaches the lid CL from the carrier C and attaches the lid CL to the carrier C. The attachment/detachment unit 43 is movable in the vertical direction Z and the front-back direction X while holding the lid CL. The lid opening/closing mechanism 41 is movable in the front-back direction X at the opening 39 in a state of holding the lid CL. The lid opening/closing mechanism 41 can be moved up and down in the vertical direction Z in a state of holding the lid CL. The lid opening/closing mechanism 41 can move downward in the vertical direction Z from the opening 39 in a state of holding the lid CL. The lid opening/closing mechanism 41 can fully open the opening 39 by lowering in a state of holding the lid CL.

First, as illustrated in FIG. 3A, the carrier C is placed on the placement table 13. A plurality of substrates W are stacked and accommodated in the carrier C, and closed by the lid CL. At this time, the lid opening/closing mechanism 41 locates the attachment/detachment unit 43 in the opening 39. Accordingly, the inside of the indexer block 5 is separated from the external atmosphere.

As illustrated in FIG. 3B, the placement table 13 moves the carrier C to the back side X. In the carrier C, the carry-in/out port CT and the lid CL are located in the opening 39. At this time, the attachment/detachment unit 43 unlocks the lid CL and holds the lid CL. The holding is performed, for example, by the attachment/detachment unit 43 adsorbing the lid CL.

As illustrated in FIG. 3C, the lid opening/closing mechanism 41 moves to the back side X. Thus, the lid CL is moved from the opening 39 to the back side X. The lid CL is moved to the inside of the indexer block 5.

As illustrated in FIG. 3D, the lid opening/closing mechanism 41 moves downward in the vertical direction Z. The lid opening/closing mechanism 41 lowers the attachment/detachment unit 43 to the lower part of the carry-in/out port CT. The lid opening/closing mechanism 41 lowers the attachment/detachment unit 43 until the upper part of the attachment/detachment unit 43 is located at the lower part of the opening 39.

As illustrated in FIG. 3E, the lid opening/closing mechanism 41 moves the attachment/detachment unit 43 downward in the vertical direction Z. The lid opening/closing mechanism 41 moves the attachment/detachment unit 43 to the lowermost part to where the lid opening/closing mechanism 41 is movable. The lid opening/closing mechanism 41 lowers the attachment/detachment unit 43 to a position where the attachment/detachment unit 43 does not overlap the opening 39 in the front-back direction X. As a result, the opening 39 is fully opened. The plurality of substrates W in the carrier C can face the indexer block 5 through the opening 39.

The lid opening/closing mechanism 41 described above includes, for example, a reflective sensor 45 in the attachment/detachment unit 43. The reflective sensor 45 is used to collect thickness shape information based on the outer edge of the substrate W. Details of the reflective sensor 45 will be described later.

### 6. Warpage of Substrate W

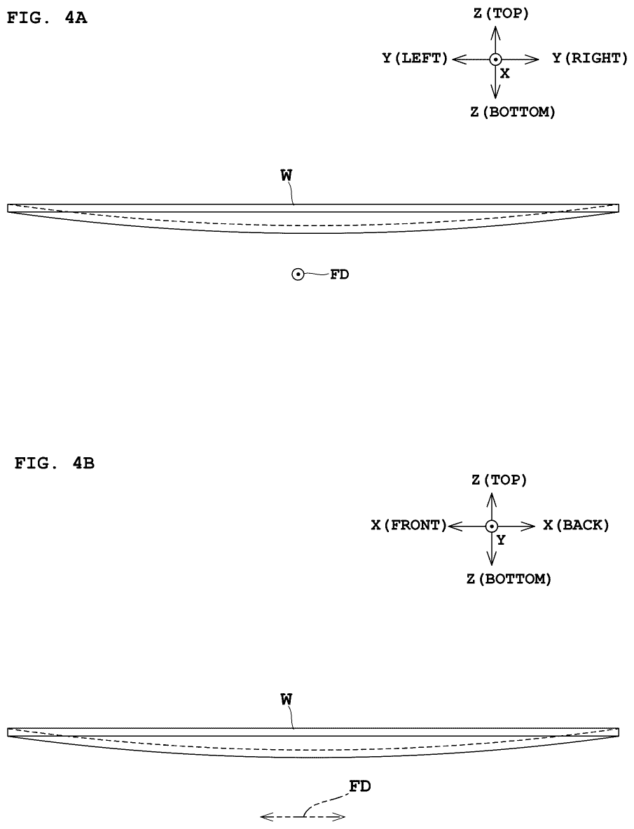

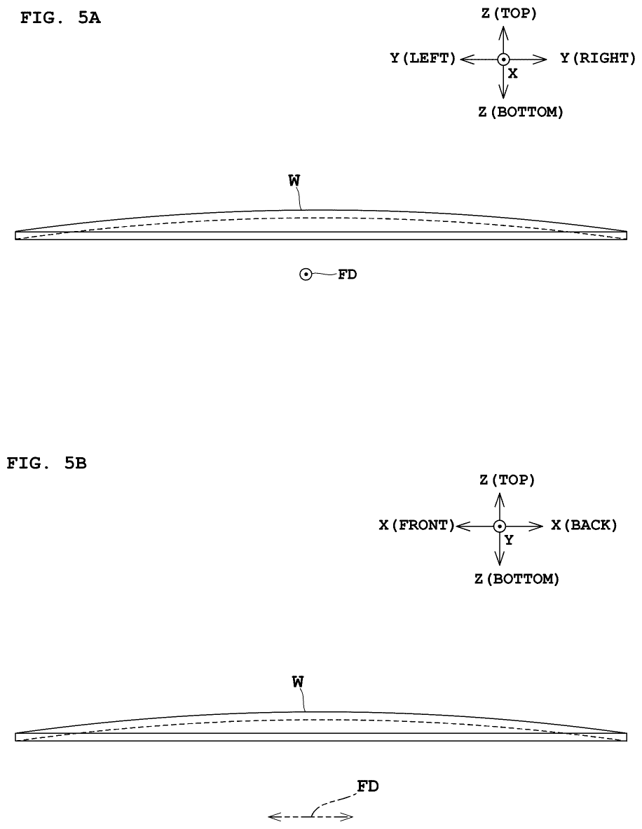

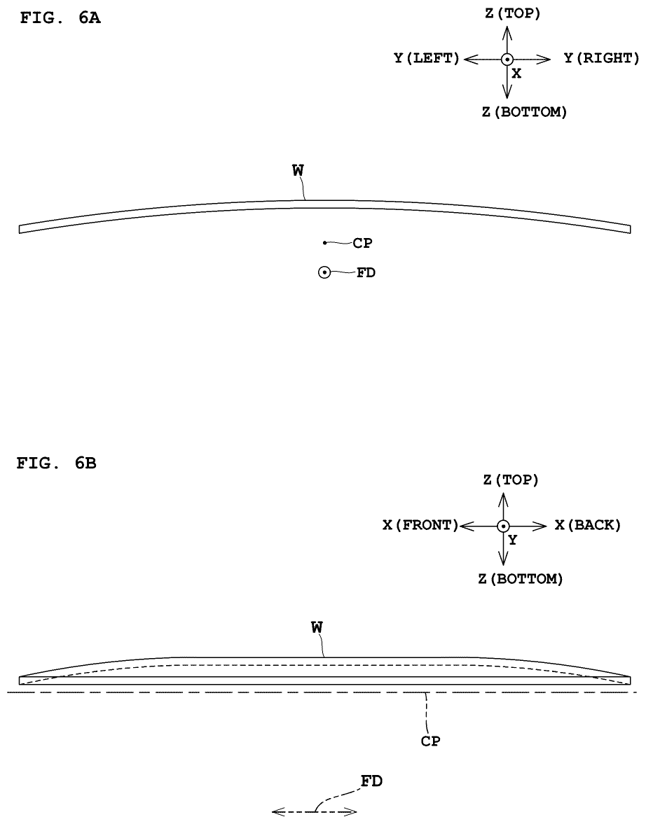

Reference is now made to FIGS. 4 to 6. FIGS. 4A and 4B are examples of the bowl shaped warped substrate, where FIG. 4A is a view as viewed from the front-back direction X, and FIG. 4B is a view as viewed from the width direction Y. FIGS. 5A and 5B are examples of the umbrella shaped warped substrate, where FIG. 5A is a view as viewed from the front-back direction X, and FIG. 5B is a view as viewed from the width direction Y. FIGS. 6A and 6B are examples of the half-pipe shaped warped substrate, where FIG. 6A is a view as viewed from the front-back direction X, and FIG. 6B is a view as viewed from the width direction Y.

The substrate W is subjected to various treatments, coated with films having different thermal expansion coefficients, and further subjected to various heat treatments. Therefore, the substrate W may be warped into a complicated shape. Typical warpage of the substrate W includes, for example, the following.

FIG. 4 illustrates a substrate W warped in a bowl shape. That is, the central portion of the substrate W is recessed, and the outer peripheral edge is at a higher position than the central portion. The substrate W warped in a bowl shape in this manner has a narrow lower interval in the vertical direction Z with respect to another substrate W accommodated below such substrate W in the carrier C. FIG. 4A is a view of the substrate W as viewed from the front-back direction X. FIG. 4A is a view of the substrate W viewed from the indexer block 5 through the carry-in/out port CT. In other words, FIG. 4A is a view as viewed from the advancing/retreating direction FD of the first hand 19 and the second hand 21 of the indexer robot CR toward the far side of the carrier C. FIG. 4B is a view of the substrate W as viewed from the width direction Y. FIG. 4B is a view of the advancing/retreating direction FD of the first hands 19 and 21 as viewed from the side. As can be seen from FIGS. 4A and 4B, the lowermost surface of the substrate W is lower than the height of the end face in the vertical direction Z.

FIG. 5 illustrates a substrate W warped in an umbrella shape. The substrate W illustrated in FIG. 5 has a shape obtained by up-down inverting the substrate W warped in a bowl shape in FIG. 4 described above. In the umbrella shaped substrate W, the outer peripheral edge is located at a position lower than the central portion, and the central portion is raised higher than the outer peripheral edge. In other words, in the umbrella shaped substrate W, the central portion is raised, and the outer peripheral edge is at a low position. The substrate W warped in a bowl shape in this manner has a narrow upper interval in the vertical direction Z with respect to another substrate W accommodated above such substrate W in the carrier C. As can be seen from FIGS. 5A and 5B, the uppermost surface of the substrate W is higher than the height of the end face in the vertical direction Z.

In the above-described bowl shaped and umbrella shaped warped substrates W, the shape of the outer edge of the substrate W is substantially the same when viewed from the front-back direction X and when viewed from the width direction Y.

FIG. 6 illustrates a substrate W warped in a half-pipe shape. In the substrate W illustrated in FIG. 6, the surface of the substrate W is separated around the axis CP on the center side as if the cylinder is cut at the axis CP on the center side. The half-pipe shaped substrate W is warped in an arc shape when viewed from the axis CP direction on the center side. The half-pipe shaped substrate W has an outer peripheral edge located at a low position and a central portion raised. However, unlike the bowl shape and the umbrella shape described above, the shape of the outer edge of the substrate W is different when viewed from the front-back direction X and when viewed from the width direction Y. In other words, the shape of the outer edge of the substrate W is different between when viewed from the front-back direction X and when viewed from the width direction Y. The substrate W warped in a half-pipe shape in this manner has a narrow upper interval in the vertical direction Z with respect to another substrate W accommodated above such substrate W in the carrier C. As can be seen from FIGS. 6A and 6B, the uppermost surface of the substrate W is higher than the height of the end face in the vertical direction Z. In FIG. 6, the axis CP on the center side is the front-back direction X, but the axis CP on the center side may be the width direction Y. In addition, there is also a warpage of a half-pipe shape as if the up-down inverted in FIG. 6.

### 7. Control System

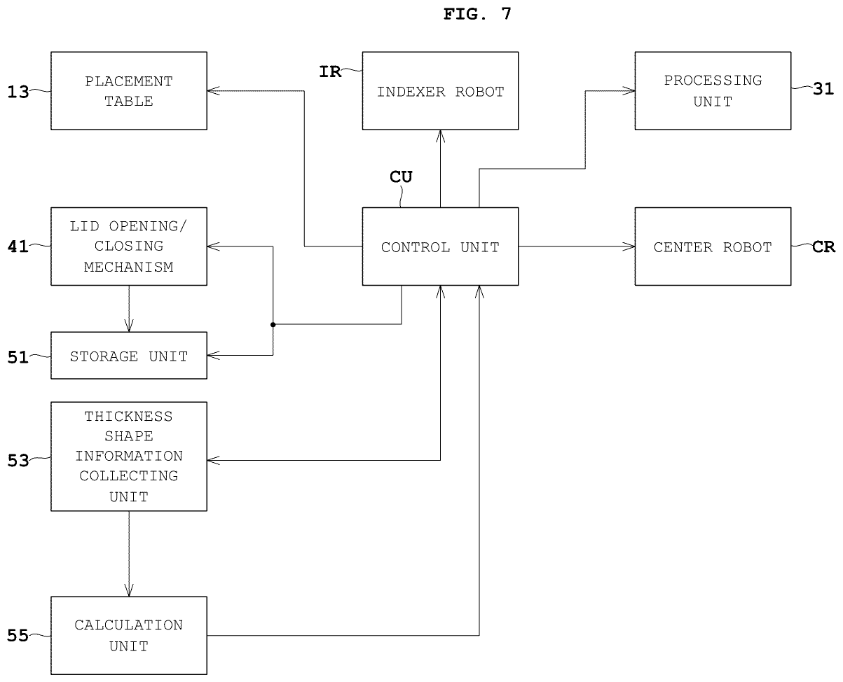

Here, a control system of the substrate processing device 1 will be described with reference to FIG. 7. FIG. 7 is a block diagram illustrating an example of a control system.

The substrate processing device 1 is totally controlled by the control unit CU. The control unit CU includes a CPU, a memory, and the like. The control unit CU operates by a program stored in advance. The control unit CU controls the movement of the carrier C in the front-back direction X on the placement table 10. The control unit CU controls the attaching and detaching operation of the lid CL by the attachment/detachment unit 43 of the lid opening/closing mechanism 41 and the raising/lowering operation of the lid opening/closing mechanism 41. When carrying out the raising/lowering operation of the lid opening//closing mechanism 41, the control unit CU carries out the raising/lowering operation while referring to the height position in the vertical direction Z output from the lid opening/closing mechanism 41. The control unit CU controls the indexer robot IR. Specifically, the control unit CU controls the movement of the first hand 19 and the second hand 21 in the advancing/retreating direction FD in the indexer robot IR, the movement of the first hand 19 and the second hand 21 in the vertical direction Z, and the turning of the indexer robot IR around the vertical direction Z. The control unit CU controls processing of the substrate W in the processing unit 31. The control unit CU controls the center robot CR. The control unit CU controls advancing/retreating movement of the first hand 33 and the second hand 35 of the center robot CR, movement of the first hand 33 and the second hand 35 in the vertical direction Z, and turning of the center robot CR around the vertical direction Z.

When the reflective sensor 45 detects the presence of the substrate W when the lid opening/closing mechanism 41 is lowered in the vertical direction Z, the control unit CU stores the height position of the lid opening/closing mechanism 41 in the vertical direction Z in the storage unit 51.

The control unit CU controls the thickness shape information collecting unit 53. The control unit CU can read a signal from the thickness shape information collecting unit 53. The thickness shape information collecting unit 53 provides a signal to a calculation unit 55. The thickness shape information collecting unit 53 collects thickness shape information as described later. The calculation unit 55 calculates height information based on the thickness shape information from the thickness shape information collecting unit 53, the height position in the vertical direction Z from the storage unit 51, and the information of the cassette C (the interval of the locking portion indicating the accommodation interval). The height information is a gap (height in the vertical direction Z) between two vertically adjacent substrates W the first hand 19 and the second hand 21 of the indexer robot IR attempt to advance/retreat.

### 8. Thickness Shape Information Collecting Unit

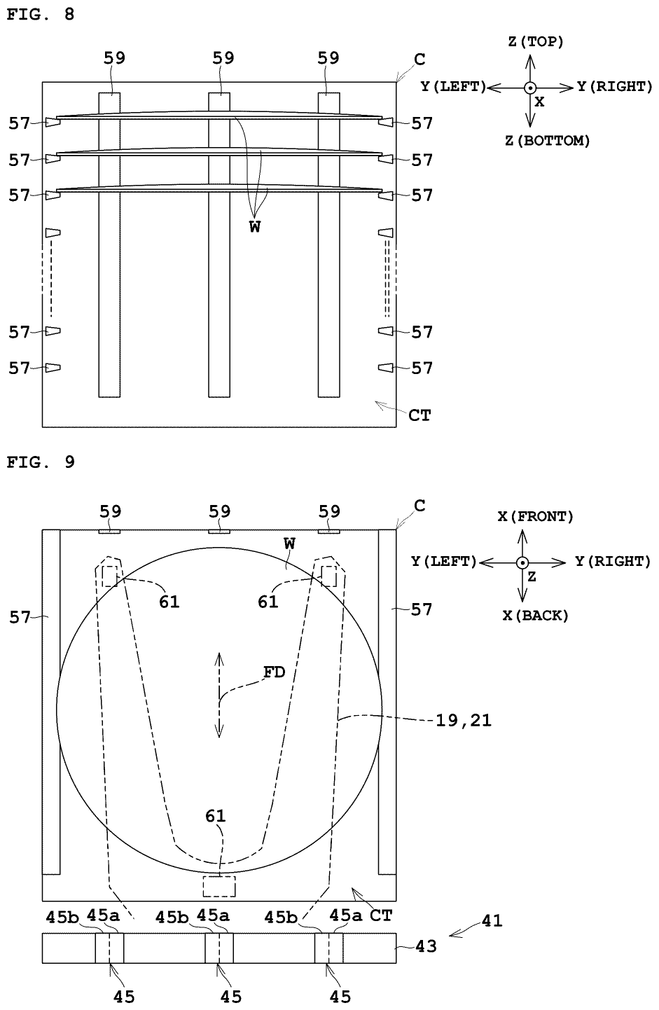

Here, the thickness shape information collecting unit 53 will be described with reference to FIGS. 8 and 9. FIG. 8 is a front view illustrating a configuration of a thickness shape information collecting unit according to the first example. FIG. 9 is a plan view illustrating a configuration of the thickness shape information collecting unit according to the first example.

The carrier C includes a plurality of locking portions 57. The plurality of locking portions 57 are provided on the inner wall of the carrier C to be spaced apart from each other in the vertical direction Z. The locking portion 57 abuts and supports the lower surface of the peripheral edge portion of the substrate W. In FIGS. 8 and 9, only the locking portion 57 provided on the inner wall in the width direction Y is illustrated for the sake of convenience of description. In practice, the locking portions 57 are formed on four surfaces of the side wall of the carrier C. In a case where the carrier C can stack and accommodate 25 substrates W, 25 locking portions 57 are formed in the vertical direction Z. The dimension of the locking portion 57 itself and the dimension of the interval between the locking portions 57 are known.

The carrier C includes a reflecting portion 59 on a side wall on the far side in the front-back direction X. The reflecting portion 59 is, for example, a mirror, a retroreflective tape, or the like. The reflecting portions 59 are arranged at a plurality of places in the width direction Y. In this example, the reflecting portions 59 are attached at three places. The reflecting portions 59 are arranged at three places in a direction orthogonal to the advancing/retreating direction FD in the horizontal direction. Three reflecting portions 59 are arranged at a plurality of places in the width direction Y. Each reflecting portion 59 extends in the vertical direction Z. As illustrated in FIG. 9, the positions of each of the reflecting portions 59 in the width direction Y are preferably positions corresponding to the first hand 19 and the second hand 21. Specifically, the first hand 19 and the second hand 21 include support pieces 61 at two places on the distal end side and one place on the basal end side. The support piece 61 abuts and supports the lower surface and the end face of the substrate W. Each reflecting portion 59 is preferably disposed in correspondence with a position where each support piece 61 exists in the width direction Y. The support piece 61 is a portion protruding upward from the first hand 19 and the second hand 21. This is because interference with the substrate W easily occurs in the first hand 19 and the second hand 21 at the time of carrying in/out the substrate W.

The reflective sensor 45 included in the lid opening/closing mechanism 41 described above is provided at a position corresponding to each reflecting portion 59. That is, the attachment/detachment unit 43 includes the reflective sensors 45 at positions facing the reflecting portions 59 in the width direction Y. Each reflective sensor 45 includes a light projecting portion 45a and a light receiving portion 45b. The light projecting portion 45a of the reflective sensor 45 emits light in the direction from the attachment/detachment unit 43 side toward the carry-in/out port CT. The light projecting portion 45a of the reflective sensor 45 emits light in a direction in which the outer side surface of the substrate W is located at the carry-in/out port CT. The direction from the attachment/detachment unit 43 side to the carry-in/out port CT is the same as the advancing/retreating direction FD of the indexer robot IR. The reflective sensor 45 cannot detect reflected light from the end face of the substrate W or the curved upper and lower surfaces. The reflective sensor 45 can detect only strong reflected light from the reflecting portion 59.

As illustrated in FIG. 9, each of the above-described reflecting portions 59 is provided inside the carrier C facing each of the reflective sensors 45 with the substrate W interposed therebetween. Each reflecting portion 59 reflects light from the light projecting portion 45a of the reflective sensor 45 toward the reflective sensor 45. The light receiving portion 45b of the reflective sensor 45 detects light irradiated from the light projecting portion 45a of the reflective sensor 45, and reflected from the reflecting portion 59. Therefore, when the reflective sensor 45 reaches the height of the outer edge of the substrate W viewed from the advancing/retreating direction FD, the irradiation light is scattered and the reflected light is not received. On the other hand, when the height of the reflective sensor 45 deviates from the outer edge of the substrate W, the reflected light reflected by the reflecting portion 59 is received. The control unit CU stores the height position of the attachment/detachment unit 43 at these time points in the storage unit 51.

The control unit CU collects the thickness shape information by the thickness shape information collecting unit 53 when lowering the lid CL by the lid opening/closing mechanism 41. The thickness shape information is information on the shape of the thickness based on the outer edge of the substrate W when the far side (front side X) of the carry-in/out port CT is viewed from the advancing/retreating direction FD of the first hand 19 and the second hand 21 in a state where the substrate W is accommodated in the carrier C. The thickness shape information includes the end face height position in the vertical direction Z of the end face on the carry-in/out port CT side among the end faces at the outer peripheral edge of the substrate W when viewed from the advancing/retreating direction FD. The thickness shape information includes a far side height position where a part of the substrate W is located away in the vertical direction Z from the end face height position of the substrate W in the front side X of the end face on the carry-in/out port CT side among the end faces at the outer peripheral edge of the substrate W when viewed from the advancing/retreating direction FD. In other words, the thickness shape information is information on the shape obtained from the outermost peripheral edge (outer shape) of the substrate W when the front side X of the substrate W is horizontally viewed from the carry-in/out port CT in the advancing/retreating direction FD. The maximum and minimum heights which are heights in the vertical direction Z in the depth direction of the substrate W in the advancing/retreating direction FD can be obtained from the thickness shape information and the height position in the raising/lowering of the lid opening/closing mechanism 41 (i.e., the reflective sensor 45 attached to the lid opening/closing mechanism 41) when the thickness shape information is collected (i.e., when the presence of the substrate W is detected).

In the following example, when the lid opening/closing mechanism 41 lowers the attachment/detachment unit 43, the height position when the outer edge of the substrate W is detected by the reflective sensor 45 is stored in the storage unit 51.

### 9. Calculation Unit

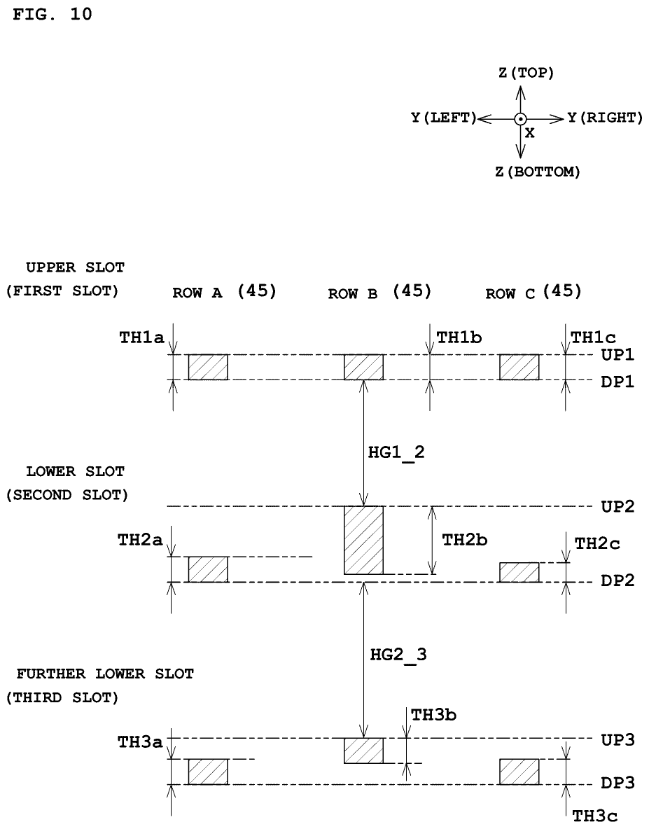

Reference is now made to FIG. 10. FIG. 10 is a schematic view for explaining the thickness shape information.

Based on the thickness shape information collected by the thickness shape information collecting unit 53, the calculation unit 55 calculates the height information of the gap between the two vertically adjacent substrates W the first hand 19 and the second hand 21 attempt to advance/retreat from the advancing/retreating direction FD to the carrier C. Here, in order to facilitate understanding of the invention, as illustrated in FIG. 10, three substrates W of a substrate W having no warpage, a substrate W having an umbrella shaped (FIG. 5) warpage, and a substrate W having a half-pipe shaped (FIG. 6) warpage will be described as being accommodated. Note that the substrate W warped in a half-pipe shape is disposed on the carrier C such that the advancing/retreating directions FD of the first hand 19 and the second hand 21 and the front-back direction X in FIG. 6A face the same direction.

Here, when the lid opening/closing mechanism 41 lowers the lid CL, specifically, the height position (i.e., the range in the height direction) from when the outer edge of the substrate W is detected by the reflective sensor 45 to when the outer edge is no longer detected at the time of the operation shown in FIGS. 3C to 3D is indicated by hatching as shown in FIG. 10. Note that, in FIG. 10, among the reflective sensors 45, the reflective sensor on the left side Y is assumed as row A, the reflective sensor in the middle is assumed as row B, and the reflective sensor on the right side Y is assumed as row C.

In the substrate W without warpage, for example, height positions in row A. row B, and row C are height positions TH1a, TH1b, and TH1c, respectively. For the sake of convenience of description, the height positions TH1a, TH1b, and TH1c illustrated as thicknesses are obtained from the height position of the storage unit 51, and thus are represented as height positions. These height positions TH1a, TH1b, and TH1c have the same thickness. Therefore, the highest position in the substrate W is the upper position UP1, and the lowest position is the lower position DP1. The upper position UP1 is the highest height position in the substrate W. The lower position DP1 is the lowest height position in the substrate W. From the relationship between these height positions, the control unit CU and the calculation unit 55 can recognize that the substrate W does not have warpage.

In the substrate W having the umbrella shaped warpage, for example, row A is the height position TH2a, row B is the height position TH2b, and row C is the height position TH2c. The height position TH2b of row B is higher than the height position TH2a of row A and the height position TH2c of row C. In this example, the height positions TH2a, TH2b, and TH2c have different thicknesses. The height position TH2a and the height position TH2c may be the same. From the relationship between these height positions, the control unit CU and the calculation unit 55 can recognize that the substrate W has an umbrella shaped warpage. In this case, the upper position UP2 is obtained from the height position TH2b of row B. The lower position DP2 is obtained from the height position TH2a of row A or the height position TH2c of row C. In this example, the height position TH2b of row B is higher than the lower position DP2. That is, the umbrella shaped warpage in this example indicates that the central portion of the lower surface of the end face of the outer peripheral edge of the substrate W is also lifted by the warpage.

When the height position TH2b of row B is lower than the height position TH2a of row A and the height position TH2c of row C, the control unit CU and the calculation unit 55 can recognize that the substrate W has a bowl shaped warpage.

In the substrate W having the half-pipe shaped warpage, for example, row A is the height position TH3a, row B is the height position TH3b, and row C is the height position TH3c. These height positions TH3a, TH3b, and TH3c have, for example, the same thickness. However, the height position TH3b of row B is different from the height position TH3a of row A and the height position TH3c of row C. Furthermore, the center position of the height position

TH3b of row B in the vertical direction Z is different from the center positions of the height position TH3a of row A and the height position TH3c of row C in the vertical direction Z. Therefore, the control unit CU and the calculation unit 55 can recognize that the substrate W has a half-pipe shaped warpage, and has the axis CP on the center side facing in the front-back direction X. In this case, the upper position UP3 is obtained from the height position TH3b of row B. The lower position DP3 is obtained from the height position TH3a of row A or the height position TH3c of row C.

In a state in which the three substrates W are accommodated in the carrier C as described above, the thickness shape information of the substrates W in the first slot includes the height positions TH1a, TH1b, and TH1c, the upper position UP1, and the lower position DP1. The thickness shape information of the substrate W in the second slot includes the height positions TH2a, TH2b, and TH2c, the upper position UP2, and the lower position DP2. The thickness shape information of the substrate W in the third slot includes the height positions TH3a, TH3b, and TH3c, the upper position UP3, and the lower position DP3. Based on these pieces of thickness shape information, the calculation unit 55 obtains height information HG1_2 of the gap between the substrates W between the first slot and the second slot and height information HG2_3 of the gap between the substrates W between the second slot and the third slot. For example, when carrying out the substrate W of the first slot, the substrate W of the first slot becomes the “target substrate”, and the height information HG1_2 of the gap between the substrate W of the first slot and the substrate W of the second slot below the first slot is calculated based on the thickness shape information of the substrate W of the first slot and the thickness shape information of the substrate W of the second slot adjacent below the first slot.

The control unit CU operates the indexer robot IR based on the height information HG1_2 and HG2_3 of the gap between the vertically adjacent substrates W obtained by the calculation unit 55. Specifically, when the first hand 19 and the second hand 21 are advanced/retreated from the advancing/retreating directions FD with respect to the carrier C to carry out the substrate W, the height positions of the first hand 19 and the second hand 21 are adjusted. For example, when carrying out the upper substrate W between the substrates W having no warpage, the hands are advanced/retreated at a predetermined height position determined in advance according to the height dimension between the slots. Alternatively, the hands are advanced/retreated at a predetermined height position determined by the teaching process. The control unit CU advances/retreats the first hand 19 and the second hand 21 by being offset from the predetermined height position according to the height information.

Specifically, when receiving the substrate W of the first slot in FIG. 10, since it is known from the thickness shape information that the substrate W of the second slot is warped upward, the first hand 19 or the second hand 21 is advanced by being offset to a position higher than the predetermined height position. This prevents interference with the substrate W of the second slot that is warped upward.

According to the present first example, the thickness shape information collecting unit 53 collects the thickness shape information based on the outer edge of the substrate W when the substrate W is viewed from the advancing/retreating direction FD toward the far side of the carry-in/out port CT in a state where the substrate W is accommodated in the carrier C. The thickness shape information includes the thickness of the substrate W not only on the near side of the carry-in/out port CT in the advancing/retreating direction FD but also on the far side. The thickness shape information includes the thickest dimension on the near side and the far side in the advancing/retreating direction FD. The calculation unit 55 calculates height information of a gap between two vertically adjacent substrates W to which the first hand 19 and the second hand 21 attempt to advance/retreat based on the thickness shape information. The control unit CU controls the transport of the indexer robot IR in consideration of the thickness of the three-dimensionally warped substrate W based on the calculated height information. Therefore, even if the substrate W is three-dimensionally warped, the first hand 19 and the second hand 21 can be prevented from interfering at the time of carry-in/out.

The correspondence relationship between the first example described above and the present invention is as follows.

The carrier C corresponds to the “accommodating container” in the present invention. The indexer robot IR corresponds to a “transporting unit” in the present invention. The first hand 19 and the second hand 21 correspond to a “holding hand” in the present invention. The reflective sensor 45, the reflecting portion 59, and the lid opening/closing mechanism 41 correspond to a “thickness shape information collecting unit” in the present invention. The lid opening/closing mechanism 41 corresponds to a “relative moving unit” in the present invention. A back side X of the advancing/retreating direction FD corresponds to a “first direction” in the present invention. The lid opening/closing mechanism 41 corresponds to an “opening/closing mechanism” in the present invention. The processing unit corresponds to a “processing unit” in the present invention. The carry-in/out block 3 and the indexer block 5 correspond to a “substrate transporting device” in the present invention.

The present invention is not limited to the above embodiment, and can be modified as follows.
(1) In the present first example, the substrate processing device 1 having the configuration as illustrated in FIGS. 1 and 2 has been described as an example. However, the present invention is not limited to such a mode. That is, the configuration of the indexer block 5 or the processing block 7 does not matter. For example, the indexer block 5 does not need to include the first hand 19 and the second hand 21, and merely needs to include at least one hand.
(2) In the present first example described above, it has been described that the substrate W having a circular shape in plan view is processed. However, the present invention is not limited to such a mode. That is, the shape of the substrate W may be a quadrangular shape or the like.
(3) In the present first example, the case where the substrate W is carried out has been described as an example, but application can also be made to a case where the substrate W is carried into the carrier C. That is, since the thickness shape information corresponds to each substrate W, interference can be prevented even when the substrate W is carried into the carrier C by referring to the thickness shape information.
(4) In the present first example, the reflective sensor 45 is provided in the lid opening/closing mechanism 41 to be raised/lowered. However, the reflective sensor 45 may be raised/lowered by a raising/lowering mechanism separate from the lid opening/closing mechanism 41. Alternatively, the reflective sensor 45 may be attached to the first hand 19 and the second hand 21, and the thickness shape information of each substrate W may be collected by raising/lowering the first hand 19 or the second hand 21. Furthermore, although the thickness shape information is collected while lowering the reflective sensor 45, the thickness shape information may be collected while raising the reflective sensor 45. Such a modification can also be performed in other examples described later.
(5) In the present first example, an example in which the back surface washing unit SSR is provided as the processing unit 31 which is a processing unit has been described. However, in the present invention, the treatment unit is not limited to the washing process. The present invention may include a processing unit configured to perform a predetermined process, for example, resist application, development process, and the like on the substrate W.

### Second Example

Hereinafter, a second example of the present invention will be described with reference to the drawings.

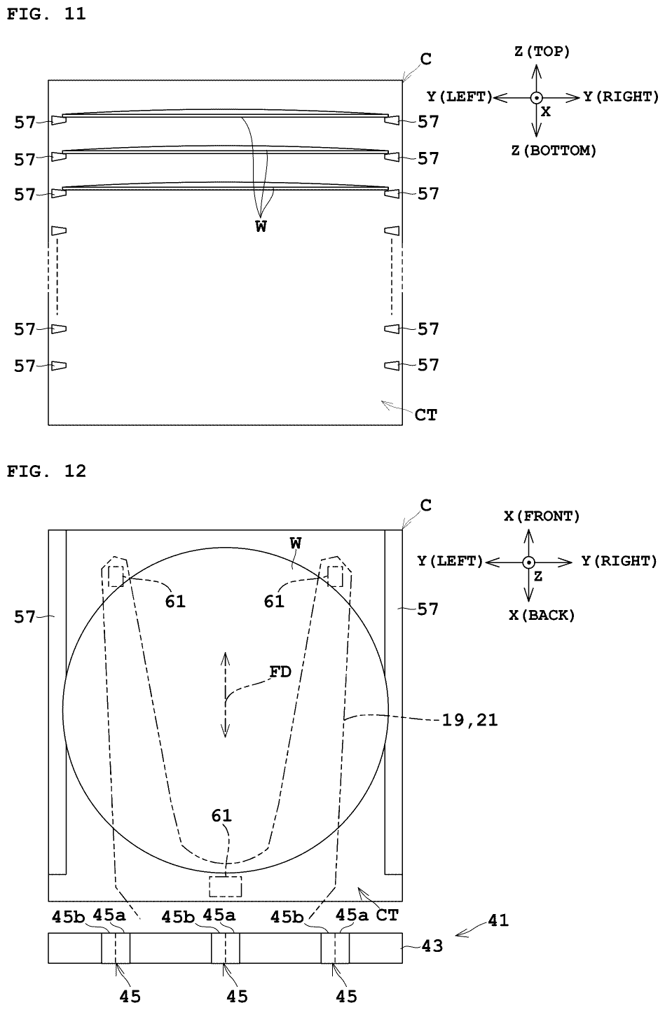

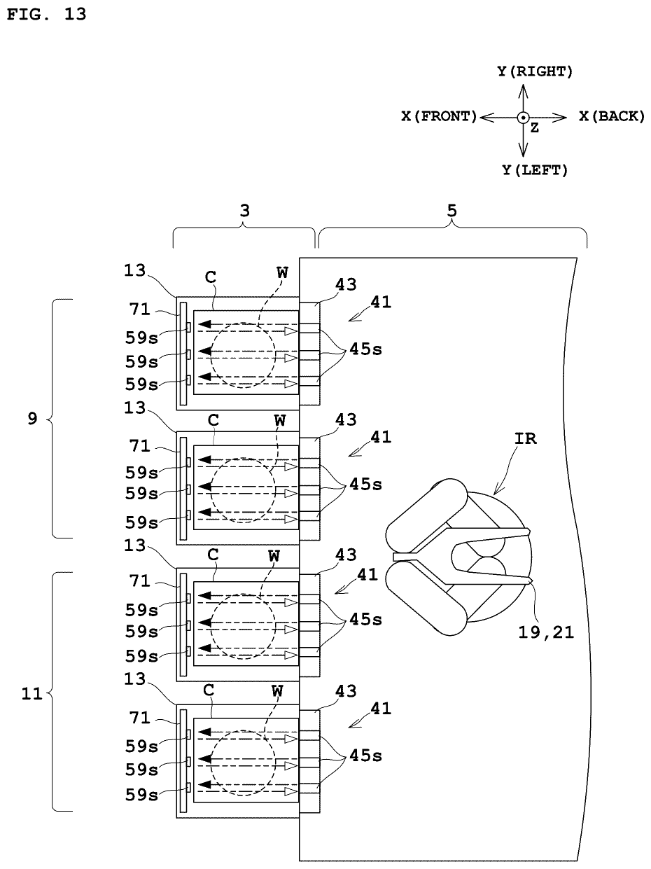

FIG. 11 is a front view illustrating a configuration of a thickness shape information collecting unit according to the second example. FIG. 12 is a plan view illustrating a configuration of the thickness shape information collecting unit according to the second example.

In the present second example, the overall configuration of the substrate processing device 1 is substantially the same as that of the first example described above. Therefore, a detailed description of the substrate processing device 1 will be omitted. Note that the same components as those of the first example are denoted by the same reference numerals, and a detailed description thereof will be omitted. The present second example is different from the first example in that the carrier C does not include the reflecting portion 59 in the first example.

In the second example, the attachment/detachment unit 43 includes a reflective sensor 45s. The reflective sensor 45s basically has the same configuration as the reflective sensor 45 of the first example described above. However, the reflective sensor 45s preferably has the irradiation light of the light projecting portion 45a stronger than that of the reflective sensor 45, and the light receiving sensitivity of the light receiving portion 45b higher than that of the reflective sensor 45. This is because in the second example, it is necessary to collect the thickness shape information of the substrate W by directly receiving reflection from the end face of the outer peripheral edge of the substrate W or the warped surface of the substrate W.

Note that, in the first example described above, the reflective sensor 45 does not receive the reflected light at a place where the substrate W exists, and the reflective sensor 45 receives the reflected light at a place where the substrate W does not exist. On the other hand, the present second example is different from the first example in terms of operation in that the reflective sensor 45s receives the reflected light at a place where the substrate W exists, and the reflective sensor 45 does not receive the reflected light at a place where the substrate W does not exist.

The present second example has a similar effect as the first example described above. Furthermore, in the present second example, since the carrier C in the first example described above does not include the reflecting portion 59, the usual commercially available carrier C can be used as it is. Therefore, the configuration can be simplified.

Note that the reflective sensor 45s and the lid opening/closing mechanism 41 described above correspond to the “thickness shape information collecting unit” in the present invention.

### Third Example

Hereinafter, a third example of the present invention will be described with reference to the drawings.

FIG. 13 is a plan view illustrating a configuration of the thickness shape information collecting unit according to the third example.

In the present third example, the overall configuration of the substrate processing device 1 is substantially the same as that of the first example described above. Therefore, a detailed description of the substrate processing device 1 will be omitted. Note that the same components as those of the first example are denoted by the same reference numerals, and a detailed description thereof will be omitted.

In the present third example, the reflecting portion 59s is disposed outside the carrier C. The carrier C is made of a material optically transparent to the irradiation light from the reflective sensor 45s provided in the attachment/detachment unit 43. The placement table 13 is provided with an attachment member 71 on the front side X of the carrier C. The attachment member 71 extends in the vertical direction Z. A reflecting portion 59s similar to that of the first example is attached to the attachment member 71. That is, the attachment member 71 is attached such that the reflecting portions 59s extending in the vertical direction Z are spaced apart from each other in the width direction Y. The attachment member 71 includes three reflecting portions 59s.

The present third example has a similar effect as the first example described above. Furthermore, in the present third example, the reflective sensor 45s and the reflecting portion 59s can be disposed outside the carrier C. Therefore, if the carrier C is made of an optically transparent material, there is no need to modify the carrier C such as attaching the reflecting portion 59.

Note that the reflective sensor 45s, the reflecting portion 59s, and the lid opening/closing mechanism 41 described above correspond to the “thickness shape information collecting unit” in the present invention.

### Fourth Example

Next, a fourth example of the present invention will be described with reference to the drawings.

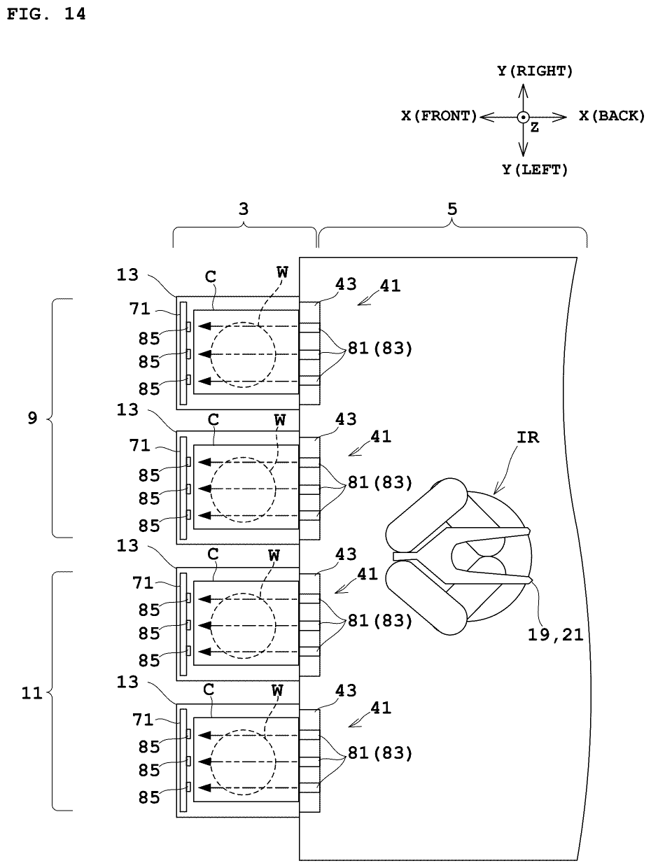

FIG. 14 is a plan view illustrating a configuration of the thickness shape information collecting unit according to the fourth example.

In the present fourth example, the overall configuration of the substrate processing device 1 is substantially the same as that of the first example described above. Therefore, a detailed description of the substrate processing device 1 will be omitted. Note that the same components as those of the first example are denoted by the same reference numerals, and a detailed description thereof will be omitted.

The present fourth example is different in the configuration in that a transmissive sensor 81 is provided. Three transmissive sensors 81 are disposed spaced apart from each other in the width direction Y. The transmissive sensor 81 includes a light projecting portion 83 and a light receiving portion 85. The light projecting portion 83 is provided in the attachment/detachment unit 43. The light projecting portion 83 emits light directed from the back side X toward the front side X of the carrier C which is the “first direction”. The light receiving portion 85 is disposed on the attachment member 71. The light receiving portion 85 is disposed on the front side X with the substrate W and the carrier C interposed therebetween. The light receiving portion 85 is arranged to face the light projecting portion 83 with the carrier C interposed therebetween in the front-back direction X. The light receiving portion 85 is disposed in a direction opposite to the “first direction”. The light receiving portion 85 is configured to be movable up and down in the vertical direction Z along the surface of the attachment member 71 on the carrier C side. The light receiving portion 85 is raised/lowered in the vertical direction Z in conjunction with the attachment/detachment unit 43.

In the present fourth example, the light receiving portion 85 does not receive the irradiation light at the place where the substrate W exists, and the light receiving portion 85 receives the irradiation light at the place where the substrate W does not exist. As a result, the thickness shape information of the substrate W is collected.

The present fourth example has a similar effect as the first example described above. Furthermore, in the present fourth example, since the detection method is the transmissive type, the detection method is less likely to be adversely affected by the reflectance of the substrate W to be detected and the reflectance of the surrounding configuration. Therefore, the detection accuracy of the thickness shape information can be improved. In addition, the light projecting portion 83 and the light receiving portion 85 can be disposed outside the carrier C. Therefore, if the carrier C is made of an optically transparent material, there is no need to modify the carrier C such as attaching the reflecting portion 59 as in the first example described above.

Note that the transmissive sensor 81 (light projecting portion 83 and light receiving portion 85) and the lid opening/closing mechanism 41 described above correspond to a “thickness shape information collecting unit” in the present invention.

The present invention is not limited to the above embodiment, and can be modified as follows.
(1) In the present fourth example, the light projecting portion 83 is provided on the back side X, and the light receiving portion 85 is provided on the front side X with the carrier C interposed therebetween. The present invention is not limited to such a configuration. That is, the positions of the light projecting portion 83 and the light receiving portion 85 may be interchanged.
(2) In the present fourth example, the light receiving portion 85 is raised/lowered in conjunction with the light projecting portion 83. However, the present invention is not limited to such a mode. For example, the position may be fixed without raising/lowering the light receiving portion 85. In this case, the light receiving portion 85 may be densely disposed in the vertical direction Z, or a line sensor may be disposed as the light receiving portion 85. The line sensor has a detection area merely including all of the plurality of substrates W in the vertical direction Z.

### Fifth Example

Next, a fifth example of the present invention will be described with reference to the drawings.

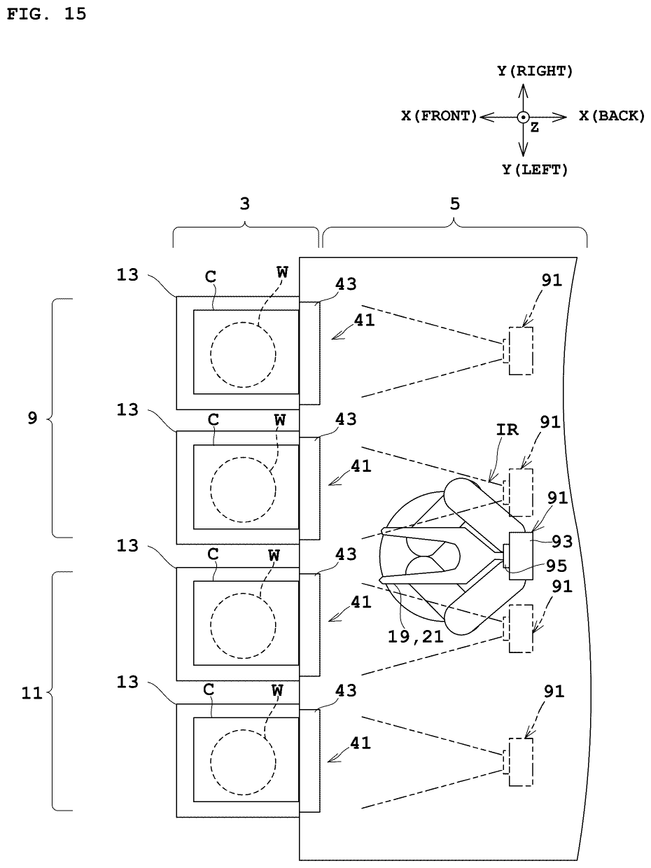

FIG. 15 is a plan view illustrating a configuration of the thickness shape information collecting unit according to the fifth example.

The overall configuration of the substrate processing device 1 is substantially the same as that of the above-described first example. Therefore, a detailed description of the substrate processing device 1 will be omitted. Note that the same components as those of the first example are denoted by the same reference numerals, and a detailed description thereof will be omitted.

In the fifth example, the indexer robot IR includes a photographing unit 91. The photographing unit 91 includes a main body 93 and a lens 95. The photographing unit 91 photographs a projection image of the substrate W as the thickness shape information. The main body 93 includes an imaging element, an image processing circuit, and the like. The lens 95 forms an image on the imaging element of the main body 93. A focusing position of the lens 95 is movable in the front-back direction X according to an external signal. That is, the lens 95 can adjust a position to focus according to a signal from the outside. The photographing unit 91 is attached to, for example, the indexer robot IR. The photographing unit 91 is movable in the vertical direction Z, the front-back direction X, and the width direction Y together with the indexer robot IR. The photographing unit 91 is disposed on the basal end side of the first hand 19 and the second hand 21.

Note that it is assumed that the photographing unit 91 can fit all the substrates W within the field of view. However, it may not be realistic to fit all the substrates W within the field of view due to optical performance such as aberration of the lens 95. In that case, the photographing unit 91 may be configured to simultaneously photograph not all the substrates W but a predetermined number (e.g., 5 sheets) of substrates W less than the number of all the substrates W. In this case, the photographing unit 91 photographs all the substrates W in the carrier C by being moved in a stepwise manner in the vertical direction Z by the indexer robot IR. Thereafter, one image in which all the substrates W are appeared may be generated by image processing and used for the calculation process of the thickness shape information.

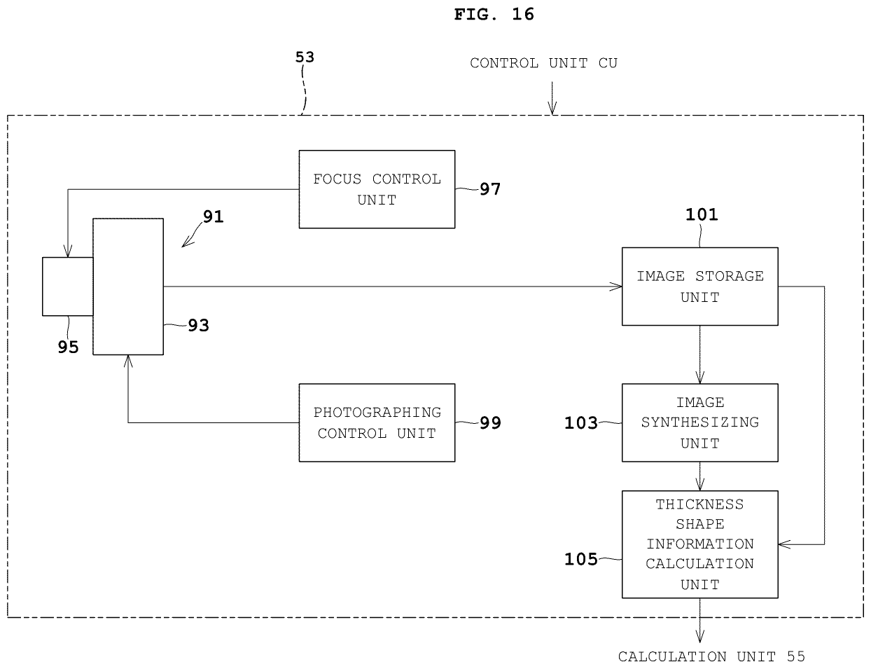

The photographing unit 91 is controlled by the thickness shape information collecting unit 53 as illustrated in FIG. 16. FIG. 16 is a block diagram illustrating an example of a thickness shape information collecting unit according to the fifth example. The thickness shape information collecting unit 53 includes a focus control unit 97, a photographing control unit 99, an image storage unit 101, an image synthesizing unit 103, and a thickness shape information calculation unit 105.

The focus control unit 97 adjusts the focus position of the lens 95 in accordance with an instruction from the control unit CU. The photographing control unit 99 sets photographing conditions according to an instruction from the control unit CU, and performs photographing by the main body 93 through the lens 95. The projection image photographed by the main body 93 is stored in the image storage unit 101. The image storage unit 101 stores images focused on at least a plurality of places.

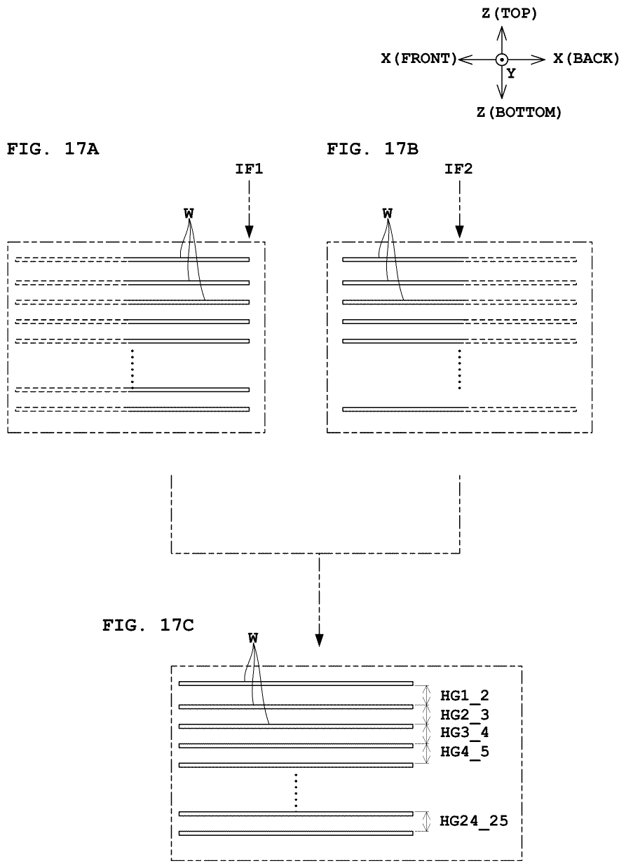

Reference is now made to FIG. 17. FIGS. 17A to 17C are schematic views for explaining a focusing position and a synthesized image. FIGS. 17A to 17C are schematic views when viewed from the width direction Y.

For example, the image storage unit 101 stores at least two projection images focused on first focusing position IF1 as illustrated in FIG. 17A and second focusing position IF2 as illustrated in FIG. 17B. The first focusing position IF1 is, for example, a part of the substrate W on the carry-in/out port CT side. The second focusing position IF2 is, for example, a part of the substrate W on the far side in the front-back direction X than the first focusing position IF1. Due to general optical characteristics, when the lens 95 is located at a position close to the substrate W serving as a subject, the distance in the front-back direction X at which the lens 95 can be regarded as being focused is short. Therefore, even if the substrate W is photographed from the indexer robot IR, it is practically not possible to focus from the end face of the substrate W on the carry-in/out port CT side to the far side of the substrate W in the front-back direction X. Therefore, the focusing position is moved to at least two places on the near side and the far side of the substrate W to photograph two projection images. The far side of the substrate W to be the second focusing position IF2 is preferably a part having the largest thickness in the substrate W.

The image synthesizing unit 103 reads and synthesizes two projection images having different focusing positions stored in the image storage unit 101 (FIG. 17C). The thickness shape information calculation unit 105 calculates the thickness shape information based on the synthesized image. The thickness shape information calculation unit 105 extracts the outer edge of the substrate W in the synthesized image by image processing such as edge enhancement, and calculates the thickness shape information based on the outer edge of the substrate W from the extracted outer edge. The thickness shape information is referred to by the calculation unit 55. In this manner, the thickness shape information can be accurately collected by setting the focusing positions in at least two places.

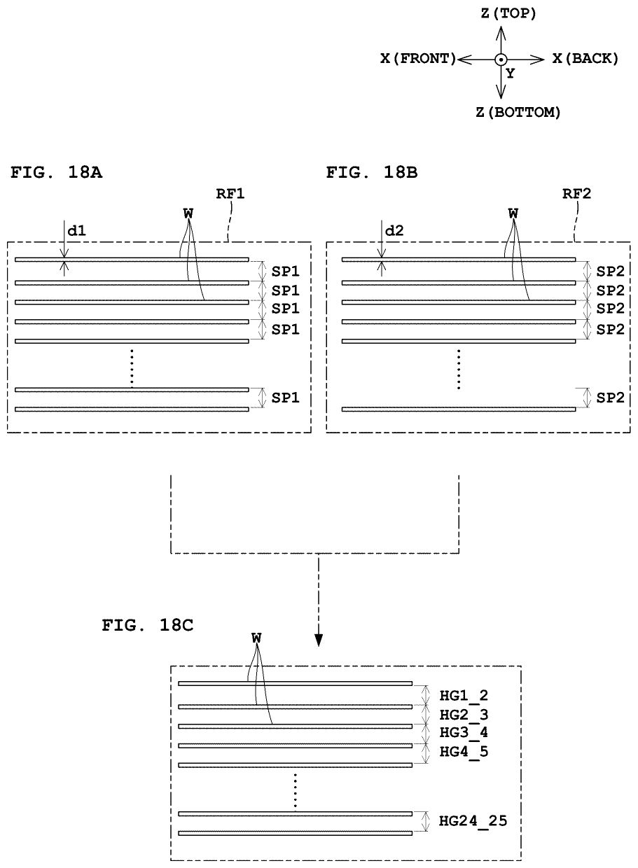

Reference is now made to FIG. 18. FIGS. 18A to 18C are schematic views illustrating examples of calibration in image processing. Note that FIGS. 18A to 18C are views of the far side of the carrier C viewed from the front-back direction X.

### 1. Calibration Process

The thickness shape information collecting unit 53 preferably performs the calibration process in the following manner.

As illustrated in FIGS. 18A and 18B, photographing is performed on the substrate W having a known size without warpage. For example, as illustrated in FIG. 18A, photographing is performed by the photographing unit 91 on a state in which a plurality of substrates W having no warpage and a first thickness dl are accommodated in the carrier C. Furthermore, as illustrated in FIG. 18B, photographing is performed by the photographing unit 91 on a state in which a plurality of substrates W having no warpage and a second thickness d2 are accommodated in the carrier C. The first thickness d1 and the second thickness d2 are different. In addition, since the dimension of the substrate W is known and the interval in the vertical direction Z of the locking portion 57 of the carrier C is known, the distance between the upper surface and the lower surface of the plurality of stacked and accommodated substrates W is also known. That is, the distance SP1 between the substrates W having the first thickness d1 and the distance SP2 between the substrates W having the second thickness d2 in the projection image are known.

Among them, a first reference image RF1 which is a projection image of a plurality of substrates W having the first thickness d1 and a second reference image RF2 which is a projection image of a plurality of substrates W having a second thickness d2 are stored in advance in the image storage unit 101. Based on the first reference image RF1 and the second reference image RF2 of the image storage unit 101, the thickness shape information calculation unit 105 sets a reference for determining a dimension of the projection image photographed by the photographing unit 91.

### 2. Calculation Process

After the calibration process is finished as described above, the thickness shape information of the substrate W is obtained when processing of the substrate W as a product is performed. Specifically, the dimension in the vertical direction Z of the synthesized image synthesized by the image synthesizing unit 103 is determined. That is, the thickness shape information calculation unit 105 recognizes the dimensions in the projection image, that is, the correspondence relationship between the distance between the pixels at one part of the substrate W in the projection image and the actual dimension from the first reference image RF1 and the second reference image RF2 including the known dimensions. Therefore, the thickness shape information calculation unit 105 obtains a dimension based on the outer edge of the substrate W appeared in the synthesized image. That is, the thickness shape information calculation unit 105 calculates the thickness shape information of the substrate W. In this manner, the thickness shape information collecting unit 53 collects the thickness shape information of the substrate W by the photographing unit 91.

According to the present fifth embodiment, the effects similar to those of the first example described above are obtained. Furthermore, the thickness shape information can be collected by photographing the projection image by the photographing unit 91. Therefore, the photographing unit 91 may be provided only on the carry-in/out port CT side of the carrier C. As a result, the configuration of the thickness shape information collecting unit 53 can be simplified. Furthermore, when the field of view is expanded in the direction in which the plurality of substrates W are stacked, a plurality of pieces of thickness shape information can be collected at the same time.

In addition, the first reference image RF1 and the second reference image RF2 are stored in advance in the image storage unit 101, and dimensions in the projection image are calculated based on the known dimensions to collect the thickness shape information. That is, since the calibration is performed, the thickness shape information can be accurately collected based on the dimension of the projection image.

The photographing unit 91, the focus control unit 97, the photographing control unit 99, the image storage unit 101, the image synthesizing unit 103, and the thickness shape information calculation unit 105 described above correspond to a “thickness shape information collecting unit” in the present invention.

The present invention is not limited to the above embodiment, and can be modified as follows.
(1) In the present fifth example, there are two focusing positions. However, the present invention is not limited thereto. That is, there may be three or more focusing positions.
(2) In the present fifth example, the indexer robot IR includes the photographing unit 91. However, the present invention is not limited to such an arrangement. That is, the arrangement position of the photographing unit 91 is not limited as long as the plurality of substrates W accommodated in the carrier C can be photographed from the carry-in/out port CT.
(3) In the present fifth example, one photographing unit 91 is associated to all the carriers C. However, the present invention is not limited to one photographing unit 91. That is, one photographing unit 91 may be arranged facing each carrier C, and a total of four photographing units 91 may be arranged. In addition, the photographing unit 91 in which the focus position of the lens 95 is fixedly set to the first focusing position IF1 and the two photographing units 91 in which the focus position of the lens 95 is fixedly set to the second focusing position IF2 may be provided. This eliminates the need for control of switching the focus position.

### Sixth Example

Next, a sixth example of the present invention will be described with reference to the drawings.

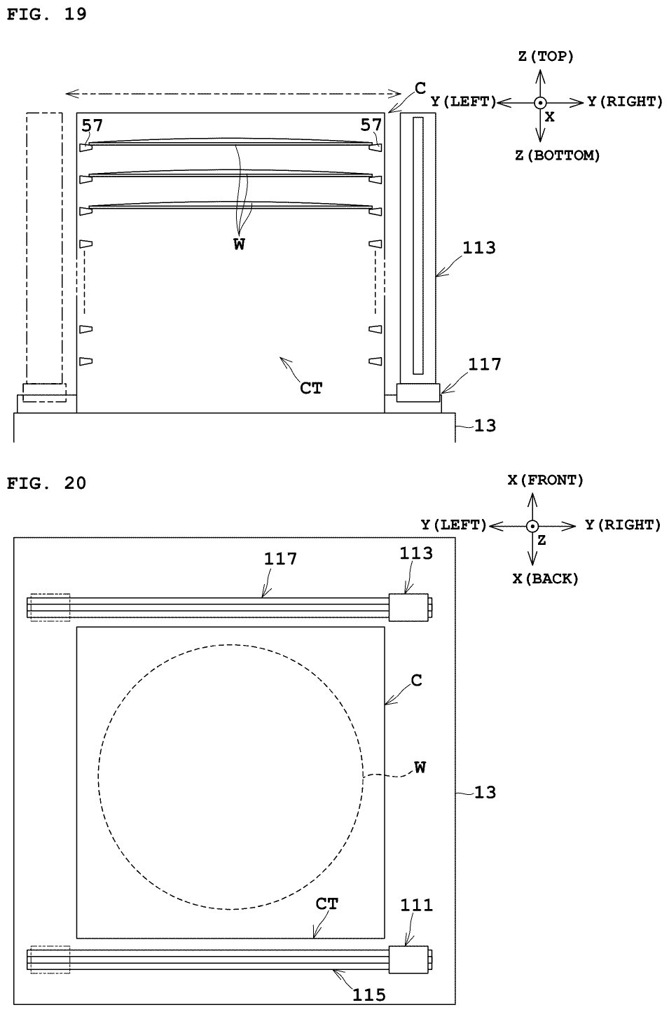

FIG. 19 is a side view illustrating an example of a thickness shape information collecting unit according to a sixth example. FIG. 20 is a plan view illustrating an example of the thickness shape information collecting unit according to the sixth example.

In the present sixth example, the overall configuration of the substrate processing device 1 is substantially the same as that of the first example described above. Therefore, a detailed description of the substrate processing device 1 will be omitted. Note that the same components as those of the first example are denoted by the same reference numerals, and a detailed description thereof will be omitted.

In the present sixth example, the thickness shape information collecting unit 53 includes a light projecting portion 111 and a line sensor 113. The light projecting portion 111 and the line sensor 113 are arranged on the placement table 13. That is, they are outside the carrier C. The light projecting portion 111 is disposed on the carry-in/out port CT side of the carrier C. The light projecting portion 111 is disposed on the placement table 13. The light projecting portion 111 emits light from the carry-in/out port CT side which is the “first direction” toward the far side of the carrier C. The carrier C is made of a material optically transparent to the light irradiated by the light projecting portion 111. The light projecting portion 111 is moved in the width direction Y by the horizontal drive unit 115. The light projecting portion 111 includes a light emitting surface that can irradiate the entire line sensor 113 with light.

The line sensor 113 is disposed on the opposite side of the “first direction” with the substrate W therebetween in plan view. The line sensor 113 includes a detection unit that is long in the vertical direction Z. The line sensor 113 has, for example, a detection unit that is long in a direction in which a plurality of substrates W are stacked and accommodated. The line sensor 113 has a detection length enough to collect the thickness shape information of all the substrates W accommodated in the carrier C. The line sensor 113 has a resolution sufficient to collect thickness shape information of the substrate W. The line sensor 113 is moved in the width direction Y by the horizontal drive unit 117. The movement by the horizontal drive unit 115 is interlocked with the movement of the horizontal drive unit 117. That is, the light projecting portion 111 and the line sensor 113 move while facing each other. The light projecting portion 111 and the line sensor 113 move in the same direction and at the same speed.

The light projecting portion 111 and the line sensor 113 are moved in conjunction with each other in the width direction Y in a state where the lid CL of the carrier C is opened. As a result, the thickness shape information of the plurality of substrates W accommodated in the carrier C can be collected.

According to the present sixth embodiment, the effects similar to those of the first example described above are obtained. Furthermore, since the line sensor 113 is used in the present sixth example, there is no need to move the substrate W in the direction in which the plurality of substrates W are stacked. Therefore, the thickness shape information of the plurality of substrates W can be efficiently collected.

The present invention is not limited to the above embodiment, and can be modified as follows.
(1) In the present sixth example, the line sensor 113 has a detection length enough to collect the thickness shape information of all the substrates W accommodated in the carrier C. However, the present invention is not limited to such a mode. That is, the line sensor 113 may have a detection length enough to collect the thickness shape information of some of the plurality of substrates W less than the number of all the substrates W all at once. In this case, the line sensor 113 may be moved in the direction in which the substrates W are stacked and accommodated and the width direction Y. Furthermore, such line sensors 113 may be disposed at three places along the width direction Y. In this case, it may be merely raised/lowered in the direction in which the substrates W are stacked and accommodated.
(2) In the present sixth example, one line sensor 113 was provided and moved in the width direction Y. However, the present invention is not limited to such a mode. For example, the three line sensors 113 may be disposed spaced apart from each other in the width direction Y. In addition, one light projecting portion 111 may be arranged to face each line sensor 113. As a result, there is no need to move the three line sensors 113 and the three light projecting portions 111 in the width direction Y.

In the embodiment of the present invention, height information of a gap between two vertically adjacent substrates is calculated. However, the present invention is not limited to the embodiment. That is, the height information of the gap between the carrier C and the substrate W may be calculated for the substrate W disposed at the bottom of the carrier C. In this case as well, similar process as in the embodiment described above is performed on the substrate W to calculate the height information.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate transporting device for transporting a substrate with an accommodating container capable of stacking and accommodating a plurality of substrates with a gap and having a carry-in/out port on one side surface, the substrate transporting device comprising:
a transporting unit having a holding hand that holds the substrate, and being configured to transport the substrate by advancing/retreating the holding hand from the carry-in/out port of the accommodating container to a gap between the substrates;
a thickness shape information collecting unit configured to collect thickness shape information based on an outer edge of the substrate for each substrate when the substrate is viewed along an advancing/retreating direction of the holding hand in a state where the substrate is accommodated in the accommodating container;
a calculation unit configured to calculate height information of a gap between two vertically adjacent substrates to which the holding hand attempts to advance/retreat based on the thickness shape information of the two vertically adjacent substrates when the transporting unit carries-in/out the substrates to/from the accommodating container; and
a control unit configured to control transport of the transporting unit based on the height information.

2. The substrate transporting device according to claim 1, wherein
the thickness shape information includes an end face height position which is a position in a height direction of an end face on the carry-in/out port side among the substrates housed in the accommodating container, and a far side height position which is on a far side of the end face and at which a part of the substrate is located away from the end face height position in the height direction.

3. The substrate transporting device according to claim 1, further comprising:
a relative moving unit configured to move a relative position between the accommodating container and the thickness shape information collecting unit in a height direction; and
a storage unit configured to store the thickness shape information of each substrate obtained by relatively moving the accommodating container and the thickness shape information collecting unit by the relative moving unit, wherein
the thickness shape information collecting unit collects the thickness shape information at a plurality of places in a horizontal direction orthogonal to an advancing/retreating direction of the holding hand, and
the calculation unit calculates the height information of a gap between vertically adjacent substrates based on the thickness shape information of each substrate stored in the storage unit.

4. The substrate transporting device according to claim 3, wherein
the thickness shape information collecting unit includes:
a light projecting portion that emits light toward an outer side surface of the substrate from a first direction toward the substrate; and
a light receiving portion that receives light emitted from the light projecting portion and reflected from a direction opposite to the first direction.

5. The substrate transporting device according to claim 4, wherein
the thickness shape information collecting unit further includes a reflecting portion that is disposed inside the accommodating container facing the light projecting portion with the substrate interposed therebetween and reflects light from the light projecting portion at the plurality of places.

6. The substrate transporting device according to claim 4, wherein
the light receiving portion receives the reflected light from the substrate.

7. The substrate transporting device according to claim 5, further comprising
an opening/closing mechanism that attaches/detaches a lid attached to the carry-in/out port of the accommodating container, and lowers the lid downward along the carry-in/out port when detaching the lid, wherein the light projecting portion and the light receiving portion are attached to the opening/closing mechanism.

8. The substrate transporting device according to claim 4, wherein
the accommodating container is made of a material optically transparent to the irradiation light from the light projecting portion,
a reflecting portion that reflects the irradiation light from the light projecting portion is provided, and
the reflecting portion is disposed outside the accommodating container.

9. The substrate transporting device according to claim 3, wherein
the thickness shape information collecting unit includes:
a light projecting portion that irradiates an outer side surface of the substrate with light from a first direction toward the substrate; and
a light receiving portion that has a function of receiving irradiation light from the light projecting portion, and is disposed outside the accommodating container in a direction opposite to a first direction with the substrate therebetween, and
the accommodating container is made of a material optically transparent to the irradiation light from the light projecting portion.

10. The substrate transporting device according to claim 1, wherein
the thickness shape information collecting unit includes a photographing unit that is disposed on the carry-in/out port side of the accommodating container and photographs a projection image as the thickness shape information.

11. The substrate transporting device according to claim 10, wherein
the photographing unit is configured to be able to adjust a focusing position,
the control unit instructs the focusing position to the photographing unit, and
the photographing unit adjusts the focusing position to at least two places of a first focusing position obtained by focusing on a part of the substrate on the carry-in/out port side and a second focusing position obtained by focusing on a part of the substrate on a far side than the first focusing position based on the instruction of the focusing position.

12. The substrate transporting device according to claim 11, further comprising an image storage unit configured to store the projection image photographed by the photographing unit, wherein
the control unit causes the photographing unit to perform photographing in a state where a plurality of substrates having a first thickness and without warpage are accommodated in the accommodating container, and causes the image storage unit to store the projection image collected at this time as a first reference image,
the control unit causes the photographing unit to perform photographing in a state where a plurality of substrates having a second thickness different from the first thickness and without warpage are accommodated in the accommodating container, and causes the image storage unit to store the projection image collected at this time as a second reference image, and
the thickness shape information collecting unit collects the thickness shape information by calculating a dimension in the projection image based on a known dimension in the first reference image and the second reference image stored in the image storage unit when performing substrate processing as a product.

13. The substrate transporting device according to claim 3, wherein
the thickness shape information collecting unit includes:
a light projecting portion that irradiates an outer side surface of the substrate with light from a first direction toward the substrate; and
a line sensor that has a function of receiving irradiation light from the light projecting portion, that is disposed outside the accommodating container in a direction opposite to a first direction with the substrate therebetween, and that has a detection area that is long in a stacking direction of the plurality of substrates accommodated inside the accommodating container, and
the accommodating container is made of a material optically transparent to the irradiation light from the light projecting portion.

14. The substrate transporting device according to claim 1, wherein
the calculation unit calculates the height information based on a shape of an outer edge of a target substrate that is a target of transport by the transporting unit and a substrate adjacent to the target substrate in the thickness shape information.

15. A substrate processing device comprising:
a substrate transporting device for transporting a substrate with an accommodating container capable of stacking and accommodating a plurality of substrates with a gap and having a carry-in/out port on one side surface; and
a processing unit configured to perform a predetermined process on a substrate transported by the substrate transporting device, wherein
the substrate transporting device includes:
a transporting unit having a holding hand that holds the substrate, and being configured to transport the substrate by advancing/retreating the holding hand from the carry-in/out port of the accommodating container to a gap between the substrates;
a thickness shape information collecting unit configured to collect thickness shape information based on an outer edge of the substrate for each substrate when the substrate is viewed along an advancing/retreating direction of the holding hand in a state where the substrate is accommodated in the accommodating container;
a calculation unit configured to calculate height information of a gap between two vertically adjacent substrates to which the holding hand attempts to advance/retreat based on the thickness shape information of the two vertically adjacent substrates when the transporting unit carries-in/out the substrates to/from the accommodating container; and
a control unit configured to control transport of the transporting unit based on the height information.
